(19) United States
(12) Patent Application Publication
(10) Pub. No.: US 2026/0202447 A1
(43) Pub. Date: Jul. 16, 2026

(54) PRECISE PEAK-TO-PEAK AMPLITUDE DETECTOR FOR HARMONIC-RICH CIRCUIT

(71) Applicant: NVIDIA Corporation, Santa Clara, CA (US)

(72) Inventors: Feilong Zhang, San Jose, CA (US); Naga Rajesh Doppalapudi, Pleasonton, CA (US); Shriram Kalusalingam, San Jose, CA (US); Gaurawa Kumar, Campbell, CA (US)

(21) Appl. No.: 19/019,810

(22) Filed: Jan. 14, 2025

(51) Int. Cl. G01R 19/04; H03K 5/01; H03K 5/24

(52) U.S. Cl. CPC G01R 19/04; H03K 5/01; H03K 5/24

(57) ABSTRACT

Technologies for providing precise peak-to-peak amplitude detection for harmonic-rich circuits are described. A peak-to-peak amplitude detector circuit can include a peak-to-peak rectifier and a linear combiner. The peak-to-peak rectifier can rectify a positive peak and a negative peak of an incoming analog signal to obtain a positive and a negative rectified signal. The linear combiner can combine and compare the positive and negative rectified signals and positive and negative target signals to obtain an output signal indicative of a peak-to-peak amplitude of the incoming analog signal.

### TECHNICAL FIELD

At least one embodiment pertains to processing resources used to detect precise peak-to-peak amplitudes for harmonic-rich circuits. For example, at least one embodiment pertains to a peak-to-peak amplitude detector circuit that rectifies both a positive peak and a negative peak of an incoming analog signal and combines and compares the positive and negative peaks with target signals to obtain an output indicative of a peak-to-peak amplitude of the incoming analog signal.

### BACKGROUND

Circuits, like Inductance (L) and Capacitance (C) oscillators (“LC oscillators”) and power amplifiers, are typically used in wireline and wireless communication systems. The amplitude control is essential for reliability and performance, i.e., 10% amplitude variation can easily cause 1 dB degradation in an LC oscillator's phase noise. Conventional peak detector cannot detect amplitude variations accurately or precisely. Conventional peak detectors detect either the positive or negative peak value of an input signal with the assumption that the input signal is symmetric. However, LC oscillators and power amplifiers are harmonic-rich circuits, and the output waveforms of these harmonic-rich circuits are not symmetric. For example, today's high-performance LC oscillators and power amplifiers (e.g., class B, class C, class F/F-1) are rich of harmonics which make the assumption no longer hold. Therefore, there is a need for accurate peak-to-peak amplitude detectors.

### BRIEF DESCRIPTION OF DRAWINGS

Various embodiments in accordance with the present disclosure will be described with reference to the drawings, in which:

FIG. 1 is a block diagram of a peak-to-peak amplitude detector circuit that detect an amplitude detection level variation of an incoming analog signal according to at least one embodiment.

FIG. 2A is a graph illustrating single-ended LC oscillation waveforms generated by a harmonic-rich circuit according to at least one embodiment.

FIG. 2B is a graph of a differential LC oscillation waveform generated by the harmonic-rich circuit according to at least one embodiment.

FIG. 2C is a graph of simulated LC oscillator phase noise versus amplitude according to at least one embodiment.

FIG. 3 is a schematic diagram of a peak-to-peak amplitude detector circuit according to at least one embodiment.

FIG. 4 is a schematic diagram of a peak-to-peak rectifier according to at least one embodiment.

FIG. 5 is a schematic diagram of a diode-based peak-to-peak rectifier according to at least one embodiment.

FIG. 6 is a schematic diagram of an amplifier-based peak-to-peak rectifier according to at least one embodiment.

FIG. 7 is a schematic diagram of an amplifier-based peak-to-peak rectifier according to at least one embodiment.

FIG. 8 is a schematic diagram of a reference generator according to at least one embodiment.

FIG. 9 is a schematic diagram of a linear combiner according to at least one embodiment.

FIG. 10 is a schematic diagram of a linear combiner according to at least one embodiment.

FIG. 11 is a schematic diagram of a linear combiner according to at least one embodiment.

FIG. 12 is a schematic diagram of a linear combiner according to at least one embodiment.

FIG. 13 is a flow diagram of an example method for determining a peak-to-peak amplitude of an incoming signal according to at least one embodiment.

FIG. 14A illustrates an example communication system with a peak-to-peak amplitude detector circuit according to at least one embodiment.

FIG. 14B illustrates a block diagram of an example communication system employing a receiver with a peak-to-peak amplitude detector circuit according to at least one embodiment.

FIG. 15 illustrates an example computer system including a spectrum hardware engine and an error correction block according to at least one embodiment.

FIG. 16 is a block diagram of a computing system having two processing devices coupled to each other and multiple networks according to at least one embodiment.

FIG. 17 is a block diagram of a computing system having a central processing unit (CPU) and a graphics processing unit (GPU) in a single integrated circuit according to at least one embodiment.

FIG. 18 is a block diagram of a computing system having tensor core graphics processing units (GPUs) according to at least one embodiment.

### DETAILED DESCRIPTION

Technologies for providing precise peak-to-peak amplitude detection for harmonic-rich circuits are described. The following description sets forth numerous specific details, such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or presented in simple block diagram format to avoid obscuring the present disclosure unnecessarily. Thus, the specific details set forth are merely exemplary. Particular implementations may vary from these exemplary details and still be contemplated to be within the scope of the present disclosure.

As described above, conventional peak detectors cannot detect amplitude variations accurately or precisely for harmonic-rich circuits because their waveforms are not symmetric.

Aspects and embodiments of the present disclosure address these problems and others by providing a precise peak-to-peak amplitude detector for harmonic-rich circuits. Aspects and embodiments of the present disclosure can detect a signal's peak-to-peak amplitude by rectifying both positive and negative input signals, and then combining the rectified signals and reference signal to obtain a peak-to-peak amplitude. The positive peak and negative peak can have the same rectifier gain. A reference generator can generate a reference voltage with high precision and temperature compensation. A linear combiner can combine the inputs to compare the input peak-to-peak amplitude and target, and then send an output signal to a processing unit. Aspects and embodiments of the present disclosure can use provide a precise measurement of the peak-to-peak amplitude with an adjustable detection range. Unlike conventional approaches, the embodiments described herein can include i) a design that detects an actual peak-to-peak amplitude, allowing it to be used for amplitude detection and control of harmonic-rich circuits, and ii) a reference generator and linear combiner that solves the process, voltage, and temperature (PVT) variations in the analog domain. The detection range can also be adjustable. Aspects and embodiments of the present disclosure can be used in harmonic-rich circuits, such as harmonic-rich circuits used in interface circuits, for example, high-speed serializer-deserializer (SerDes) circuits.

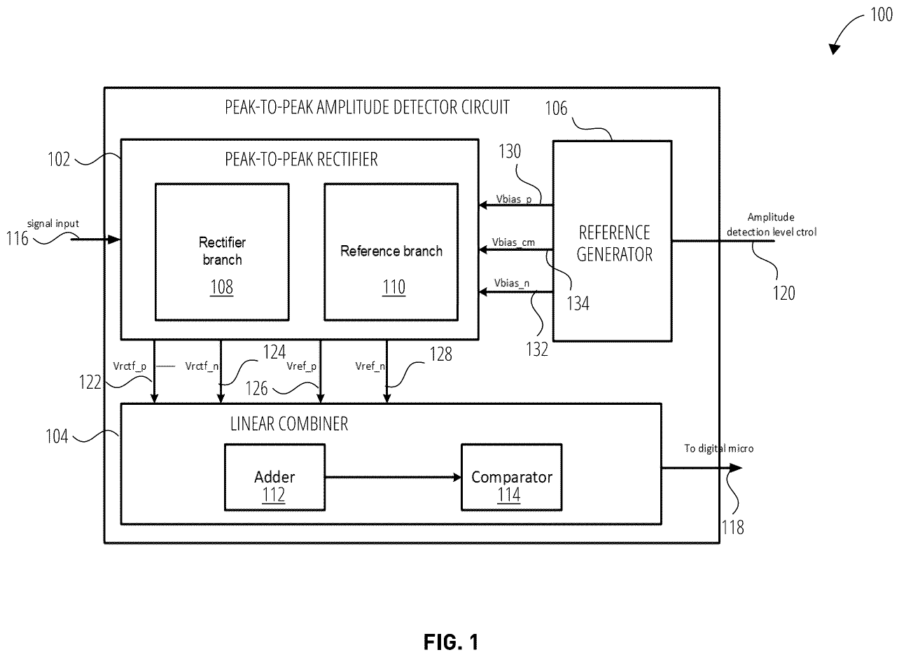

FIG. 1 is a block diagram of a peak-to-peak amplitude detector circuit 100 that detect an amplitude detection level variation of an incoming analog signal 116 according to at least one embodiment. The peak-to-peak amplitude detector circuit 100 includes at least a peak-to-peak rectifier 102 and a linear combiner 104. In some embodiments, the peak-to-peak amplitude detector circuit 100 also includes a reference generator 106. The reference generator 106 can be part of another circuit than the peak-to-peak amplitude detector circuit 100 and provide the corresponding signals to the peak-to-peak rectifier 102 or linear combiner 104, as described below.

In at least one embodiment, the peak-to-peak rectifier 102 can receive the incoming analog signal 116. The peak-to-peak rectifier 102 can rectify a positive peak of the incoming analog signal 116 to obtain a positive rectified signal 122. The peak-to-peak rectifier 102 can rectify a negative peak of the incoming analog signal 116 to obtain a negative rectified signal 124. The linear combiner 104 can combine and compare the positive rectified signal 122 and the negative rectified signal 124 with a positive target signal 126 and a negative target signal 128 to obtain an output signal 118. The output signal 118 is indicative of a peak-to-peak amplitude of the incoming analog signal 116. In at least one embodiment, the linear combiner 104 can output the output signal 118 to a digital processing circuit. In another, the linear combiner 104 can output the output signal 118 to an analog processing circuit. In some cases, the receiving circuit of the output signal 118 can be the same receiving circuit as the incoming analog signal 116. In other cases, the receiving signal of the output signal 118 can be different than the receiving circuit as the incoming analog signal 116.

In at least one embodiment, the linear combiner 104 can receive the positive target signal 126 and the negative target signal 128 from the peak-to-peak rectifier 102, as illustrated in FIG. 1. In another embodiment, the linear combiner 104 can receive the positive target signal 126 and negative target signal 128 from the reference generator 106 directly.

In at least one embodiment, the peak-to-peak rectifier 102 includes a rectifier branch 108 and a reference branch 110. The reference branch 110 can generate the positive target signal 126 and the negative target signal 128 based on bias signals received from the reference generator 106. As illustrated in FIG. 1, the reference generator 106 can a positive bias signal 130, a negative bias signal 132, and a common mode signal 134. The rectifier branch 108 can receive the incoming analog signal 116 and the common mode signal 134. The rectifier branch 108 can rectify the incoming analog signal 116 to obtain the positive rectified signal 122 and the negative rectified signal 124, as described above. The rectifier branch 108 can provide the positive rectified signal 122 and the negative rectified signal 124 to the linear combiner 104. The reference branch 110 can receive the positive bias signal 130 and the negative bias signal 132 from the reference generator 106. The reference branch 110 can generate the positive target signal 126 and the negative target signal 128 using the positive bias signal 130 and the negative bias signal 132, respectively. The reference branch 110 can provide the positive target signal 126 and the negative target signal 128 to the linear combiner 104.

In at least one embodiment, the linear combiner 104 can combine the following four signals: positive rectified signal 122, negative rectified signal 124, positive target signal 126, and negative target signal 128. The linear combiner 104 can then compare differences between the positive and negative rectified signals 122, 124, and the positive and negative target signals 126, 128 to obtain the output signal 118 indicative of the peak-to-peak amplitude of the incoming analog signal 116.

In at least one embodiment, the linear combiner 104 includes an adder 112 and a comparator 114. The adder 112 can add the signals and the comparator 114 can compare signals {(vrect_p−vrefp)+(vrect_n−vrefn)}. The linear combiner 104 includes a subtractor and a comparator 114. The subtractor can subtract signals and the comparator 114 can compare signals (e.g., {(vrect_p−vrect_n)−(vrefp−vrefn)}). In another embodiment, the linear combiner 104 can compare {(vrect_p−vrect_n)−(vrefp−vrefn)} in other ways. For example, in a first stage, a first subtractor can calculate vrect_p and vrect_n and, in a second stage, a second subtractor can calculate vrefp and vrefn. Then, a comparator can compare intermediate signals.

In at least one embodiment, the linear combiner 104 includes a first comparator to compare the positive rectified signal 122 and the positive target signal 126 to obtain a first intermediate signal. The linear combiner 104 also includes a second comparator to compare the negative rectified signal 124 and the negative target signal 128 to obtain a second intermediate signal. The adder 112 can combine the first intermediate signal and the second intermediate signal to obtain the output signal 118 indicative of the peak-to-peak amplitude of the incoming analog signal 116.

In at least one embodiment, the reference generator 106 can generate the positive target signal 126 and the negative target signal 128, instead of the reference branch 110 of the peak-to-peak rectifier 102. In this embodiment, the linear combiner 104 can include a first comparator to compare the positive rectified signal 122 and the positive target signal 126 to obtain a first intermediate signal, a second comparator to compare the negative rectified signal 124 and the negative target signal 128 to obtain a second intermediate signal, and an adder 112 to combine the first intermediate signal and the second intermediate signal to obtain the output signal 118 indicative of the peak-to-peak amplitude of the incoming analog signal 116. Alternatively, other methods of using these four signals to combine and compare are possible.

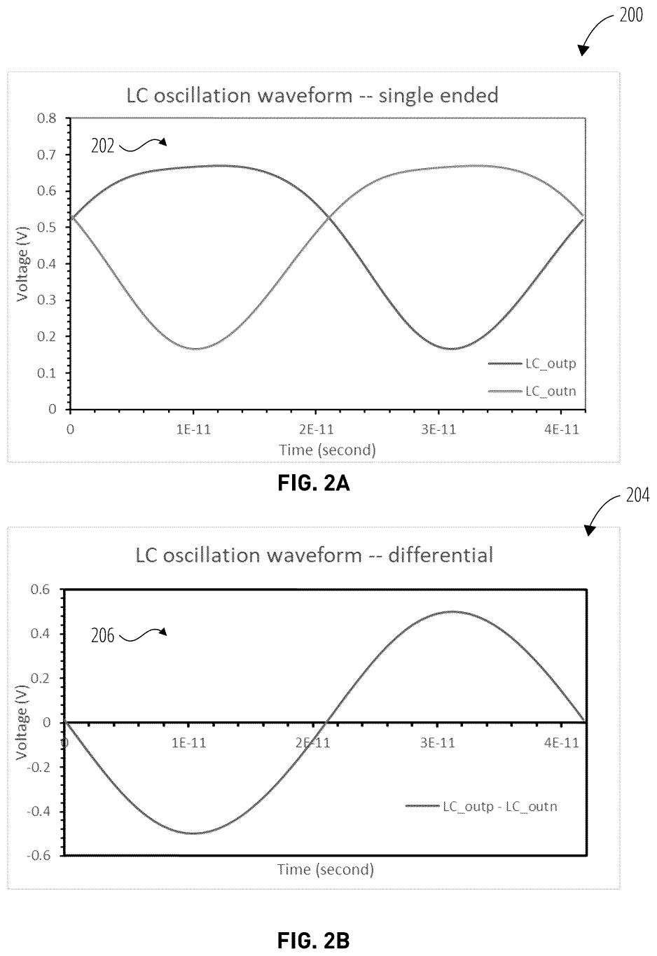

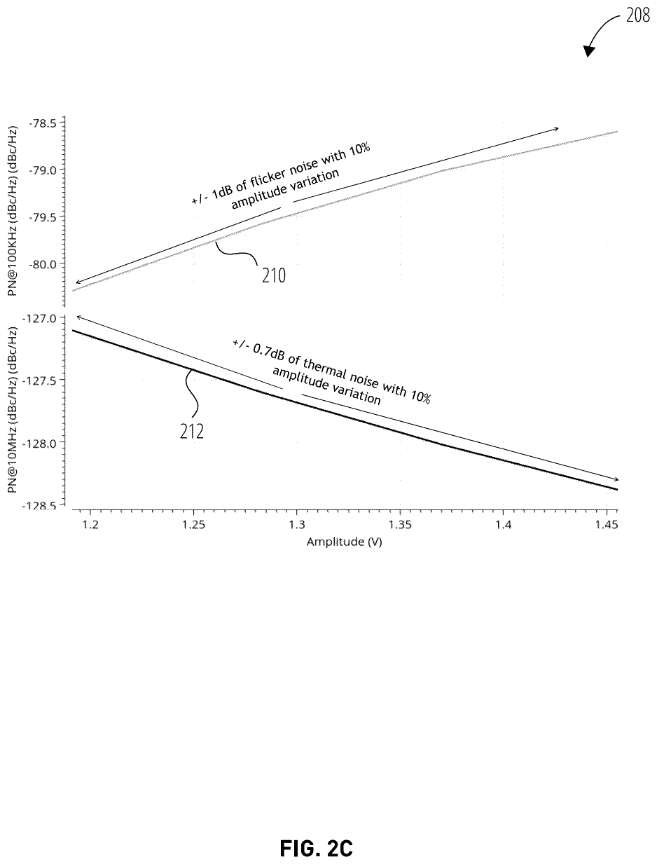

As described herein, the incoming analog signal 116 can be generated by a harmonic-rich circuit, such as an LC oscillator. In a harmonic-rich circuit (i.e oscillator), a symmetric differential waveform does not guarantee symmetric single-ended waveforms, as illustrated in FIG. 2A.

FIG. 2A is a graph 200 illustrating single-ended LC oscillation waveforms 202 generated by a harmonic-rich circuit according to at least one embodiment. FIG. 2B is a graph 204 of a differential LC oscillation waveform 206 generated by the harmonic-rich circuit according to at least one embodiment. Even though the differential LC oscillation waveform 206 can be symmetric, as illustrated in FIG. 2B, the single-ended LC oscillation waveforms 202 can be quite asymmetrical, as illustrated in FIG. 2A. Prior peak detectors would detect only one of the single-ended LC oscillation waveforms 202 to detect only the positive peak or only the negative peak. However, these prior peak detectors were prone to this asymmetry issue and cause measurement error. This amplitude error can easily be larger than 10%. A 10% amplitude error can have a big impact to circuit and system performance. For example, for an LC oscillator, there can be +/−1 dB variation in flicker noise and −/+0.7 dB in thermal noise, as illustrated in FIG. 2C.

FIG. 2C is a graph 208 of simulated LC oscillator phase noise versus amplitude according to at least one embodiment. The graph 208 shows that the LC oscillator has +/−1 dB variation in flicker noise 210 and −/+0.7 dB in thermal noise 212.

Referring back to FIG. 1, the peak-to-peak amplitude detector circuit 100 can be used to resolve the asymmetry issue, as well as PVT variations.

As described above, the peak-to-peak rectifier 102 can rectify both the positive and negative peaks. The reference generator 106 can be used to generate reference voltages with temperature compensation and adjustable level. The reference generator 106 can generate reference voltages with high precision and temperature compensation. The reference voltages can be the positive bias signal 130, negative bias signal 132, and/or the positive target signal 126 and negative target signal 128 received by the linear combiner 104. The linear combiner 104 can combine the inputs to compare the input peak-to-peak amplitude and target, then send the output signal 118 to a processing unit (e.g., digital or analog circuit). In at least one embodiment, the output signal 118 can be output to an Integrate-and-Dump Filter (IDF) to reduce noise in the output signal 118, representing the peak-to-peak amplitude of the incoming analog signal 116. With different input waveform shapes for PVT variations, the amplitude detection level variation detected by the peak-to-peak amplitude detector circuit 100 can be less than 1%.

In at least one embodiment, the reference generator 106 can receive a control signal 120 from an external circuit, such as a controller, a digital signal processing circuit or an analog processing circuit that receives the incoming analog signal 116, or the like. In at least one embodiment, the reference generator 106 can include a voltage digital-to-analog converter (DAC) that converts a digital code or digital signal (e.g., control signal 120) into a reference voltage. In at least one embodiment, the voltage DAC can be a resistor ladder. Alternatively, other circuits can be used to generate reference voltages.

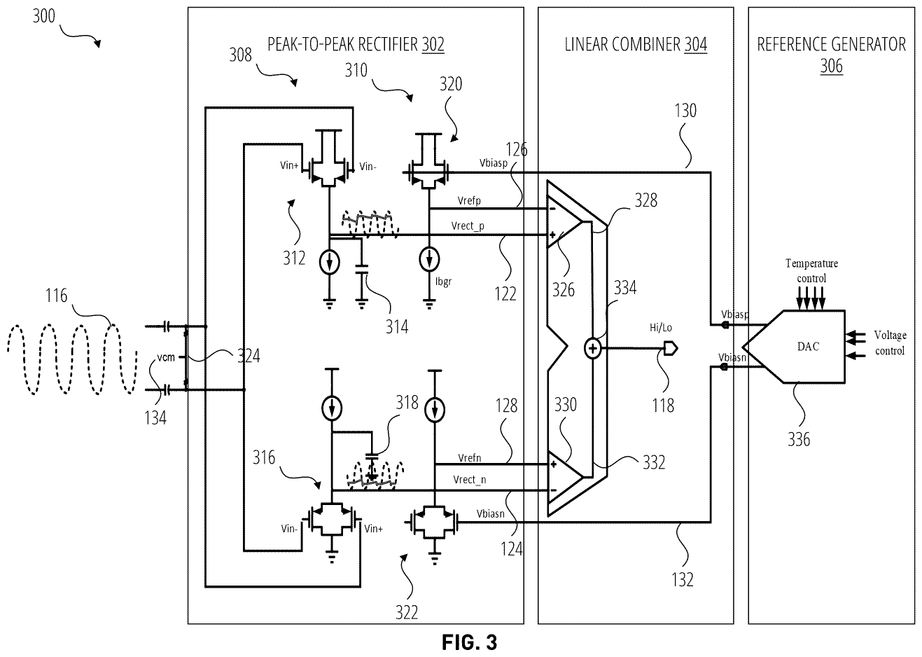

FIG. 3 is a schematic diagram of a peak-to-peak amplitude detector circuit 300 according to at least one embodiment. The peak-to-peak amplitude detector circuit 300 can be the peak-to-peak amplitude detector circuit 100 of FIG. 1, except FIG. 3 illustrates at least one circuit implementation of the peak-to-peak amplitude detector circuit 100 of FIG. 1. The peak-to-peak amplitude detector circuit 300 includes a peak-to-peak rectifier 302, a linear combiner 304, and a reference generator 306, each similar to the peak-to-peak rectifier 102, the linear combiner 104, and the reference generator 106 of FIG. 1, respectively.

As illustrated in FIG. 3, the peak-to-peak rectifier 302 includes a rectifier branch 308 and a reference branch 310. The rectifier branch 308 includes a first transistor pair 312 and a first capacitor 314 to generate the positive rectified signal 122 from the incoming analog signal 116. Gates of the first transistor pair 312 are coupled to differential inputs that receive the incoming analog signal 116. The peak-to-peak rectifier 302 includes a common voltage node 324 that is coupled between the differential inputs and receives the common mode signal 134 from the reference generator 306. The rectifier branch 308 also includes a second transistor pair 316 and a second capacitor 318 to generate the negative rectified signal 124. Gates of the second transistor pair 316 are coupled to the differential inputs that receive the same incoming analog signal 116.

In at least one embodiment, the reference branch 310 includes a third transistor pair 320 to generate the positive target signal 126. Gates of the third transistor pair 320 are coupled to receive the positive bias signal 130 from the reference generator 306. The reference branch 310 also includes a fourth transistor pair 322 to generate the negative target signal 128. Gates of the fourth transistor pair 322 are coupled to receive the negative bias signal 132 from the reference generator 306.

As illustrated in FIG. 3, the linear combiner 304 includes a first comparator 326 to compare the positive rectified signal 122 and the positive target signal 126 to obtain a first intermediate signal 328, a second comparator 330 to compare the negative rectified signal 124 and the negative target signal 128 to obtain a second intermediate signal 332, and an adder 334 to combine the first intermediate signal 328 and the second intermediate signal 332 to obtain the output signal 118 indicative of the peak-to-peak amplitude of the incoming analog signal 116. In at least one embodiment, the output signal 118 is a digital value of 1 or 0, representing a high or low value. In another embodiment, the reference generator 306 generates the positive target signal 126 and negative target signal 128 without the reference branch 310. However, it should be noted that the reference branch 310 can easily generate the positive target signal 126 and the negative target signal 128 using similar devices used for rectification, ensuring a comparison of voltages from devices in the same voltage domain and using similar devices. Using the reference branch 310 also allows the transistor pairs to be adjusted by the reference generator 306 to different target voltages.

As illustrated in FIG. 3, the reference generator 306 includes a voltage DAC 336 that generates voltage references: positive bias signal 130 (Vbiasp), negative bias signal 132 (Vbiasn), and common mode signal 134 (Vcm). The voltage DAC 336 has temperature control to control temperature coefficient for low temperature variation of detection threshold. The voltage DAC 336 also has voltage control to set detection threshold level. The reference generator 306 can include a programmable current source coupled to the sequence of resistors. The programable current source can generate a current with temperature slope compensation.

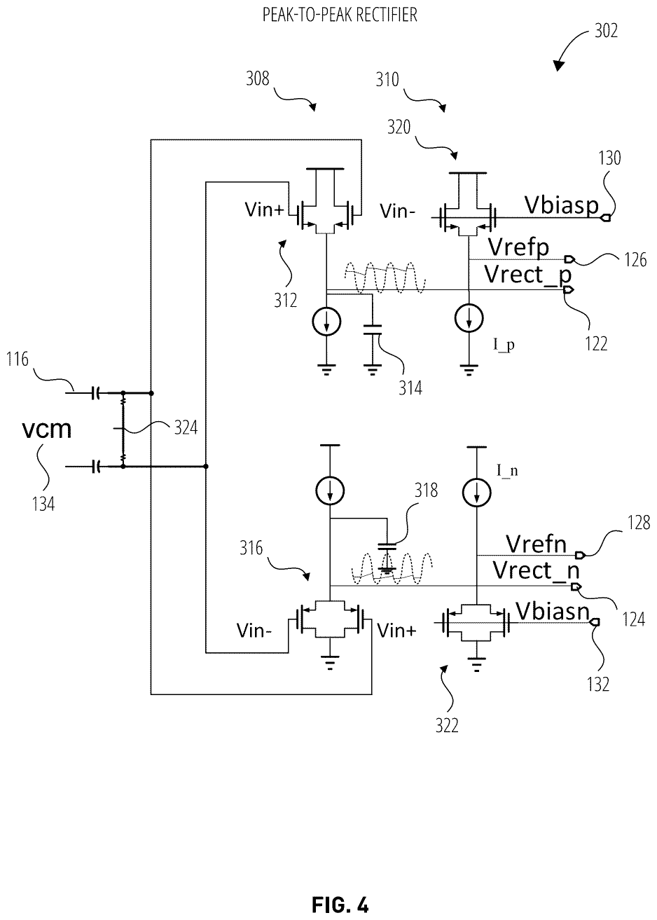

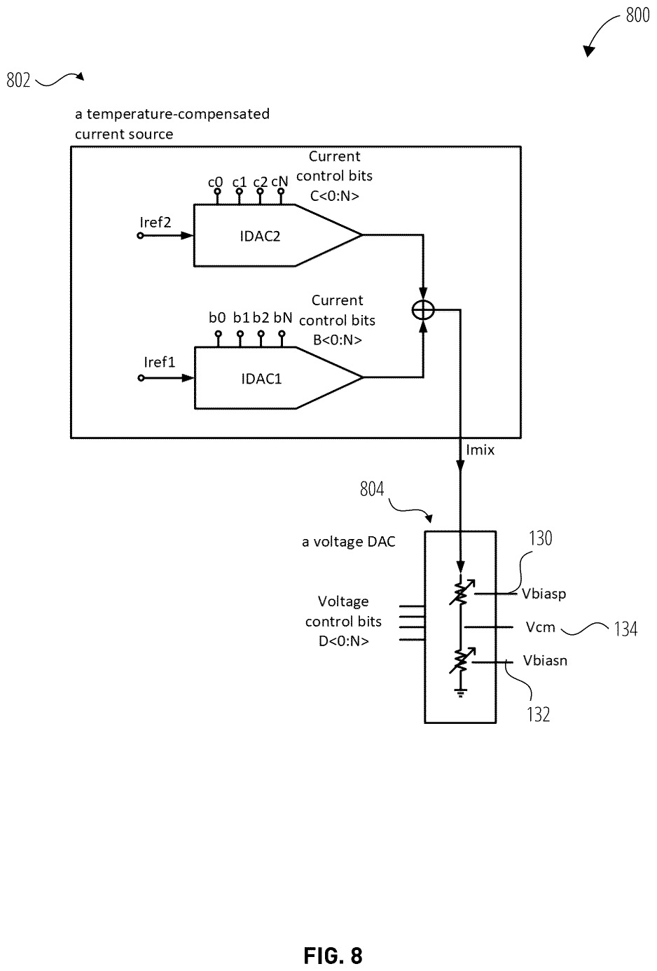

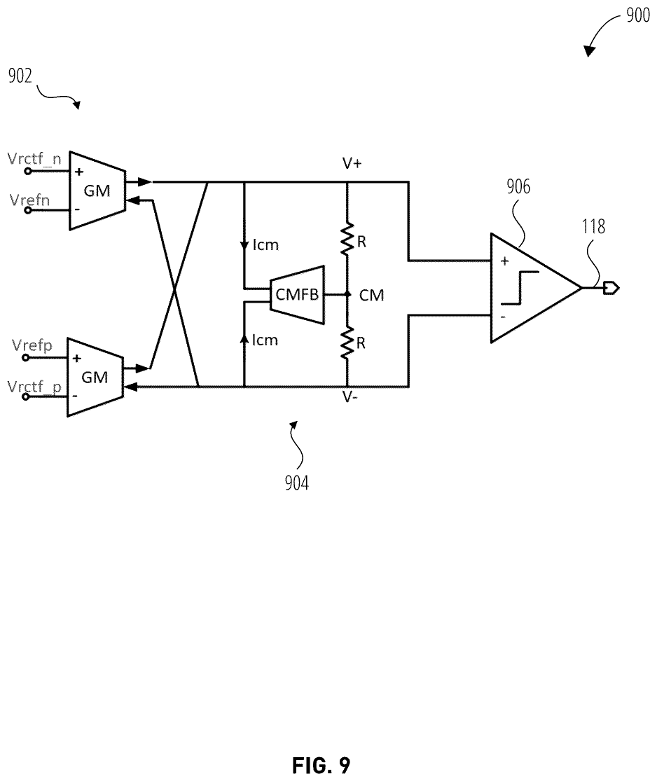

In another embodiment, the reference generator 306 includes a resistor divider network. The resistor divider network can be a sequence of resistors in series, with taps at each junction, a first set of switched resistors coupled in parallel to a first resistor of the sequence of resistors, and a second a second set of switched resistors coupled in parallel to a second resistor of the sequence of resistors. A center junction of the resistor divider network can be used to generate the common mode signal 134. A first set of switched resistors can be programmable to generate the positive bias signal 130. A second set of switched resistors can be programmable to generate the negative bias signal 132. Additional details of the peak-to-peak rectifier 302 are described below with respect to FIG. 4 to FIG. 7. Additional details of the reference generator 306 are described below with respect to FIG. 8. Additional details of the linear combiner 304 are described below with respect to FIG. 9 to FIG. 12.

FIG. 4 is a schematic diagram of a peak-to-peak rectifier 302 according to at least one embodiment. The peak-to-peak rectifier 302 of FIG. 4 is the same as peak-to-peak rectifier 302 of FIG. 3, except the operations of the peak-to-peak rectifier 302 are described in more detail here. As described above, the peak-to-peak rectifier 302 receive the incoming analog signal 116 at differential inputs. The first transistor pair 312 can generate the positive rectified signal 122 using the following Equation 1:

$${V}_{rect \_ p} = {V}_{cm} + {G}_{p} ( {I}_{p} , T ) \times {V}_{{peak}_{p}} - {V}_{gs \_ n} ( T ) , \qquad ( Equation 1 )$$

where Gₚ(Iₚ, T) is the positive peak rectifier gain, which is related to bias current Iₚ and temperature T. The second transistor pair 316 can generate the negative rectified signal 124 using the following Equation 2:

$${V}_{rect \_ n} = {V}_{cm} - {G}_{n} ( {I}_{n} , T ) \times {V}_{{peak}_{n}} - {V}_{gs \_ p} ( T ) , \qquad ( Equation 2 )$$

where Gₙ(Iₙ, T) is the negative peak rectifier gain, which is related to bias current In and temperature T. The third transistor pair 320 can generate the positive target signal 126 using the following Equation 3:

$${V}_{refp} = {V}_{biasp} - {V}_{gs \_ n} ( T ) \qquad ( Equation 3 )$$

The fourth transistor pair 322 can generate the negative target signal 128 using the following Equation 4:

$${V}_{refn} = {V}_{biasn} + {V}_{{gs}_{p}} ( T ) \qquad ( Equation 4 )$$

By controlling Iₙ, and Iₙ, the positive and negative peak rectifier grains can be set to be equal, Gₚ(Iₚ, T)=Gₙ(Iₙ, T), and written as G(T). As described above, The linear combiner 104 can combine and compare the four signals: positive rectified signal 122, negative rectified signal 124, positive target signal 126, and negative target signal 128 to obtain the output signal indicative of a peak-to-peak amplitude of the incoming analog signal 116 according to the following Equation 5:

$$( {V}_{{rect}_{p}} - {V}_{{rect}_{n}} ) - ( {V}_{refp} - {V}_{refn} ) \qquad ( Equation 5 )$$

This equation can be rewritten into Equation 6 and Equation 7 by substituting the Equation 1, Equation 2, Equation 3, and Equation 4 into Equation 5, as follows:

$$Output = G ( T ) * \text{?} - ( {V}_{biasp} - {V}_{biasn} ) \qquad ( Equation 6 )$$

$$Output = G ( T ) * ( \text{?} + \text{?} ) - ( \text{?} - \text{?} ) \qquad ( Equation 7 )$$

$$\text{?} \text{indicates text missing or illegible when filed}$$

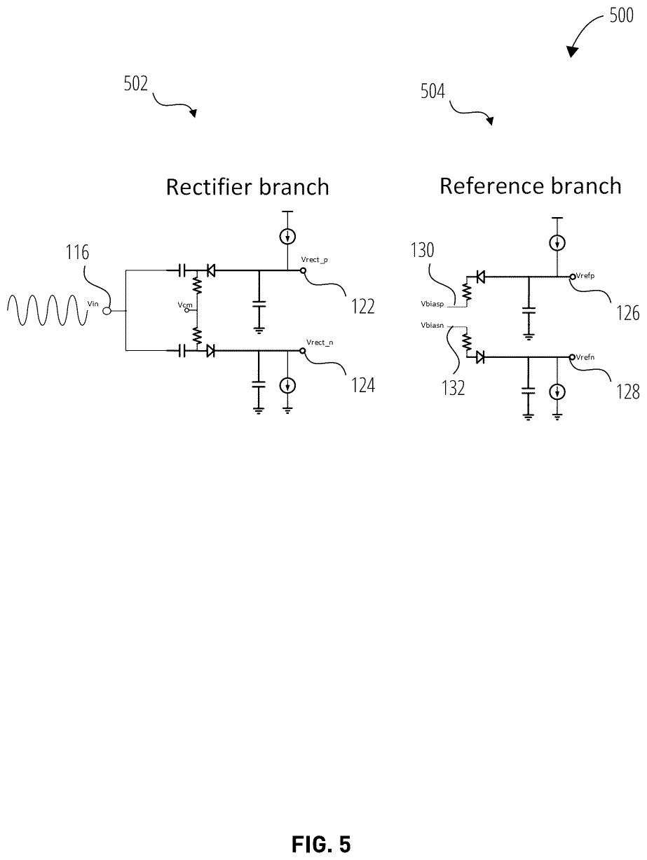

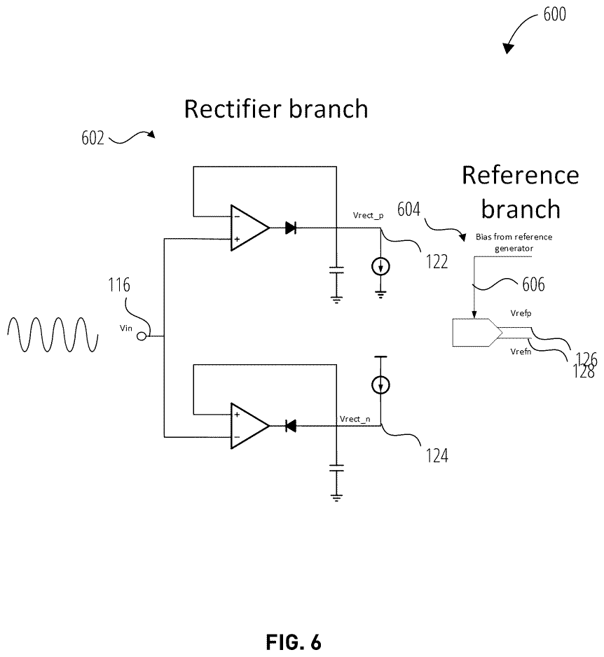

It should be noted that the peak-to-peak rectifier 302 is one implementation of the peak-to-peak rectifier 102. In other embodiments, the peak-to-peak rectifier 102 can include diode-based rectifiers, such as illustrated in FIG. 5. In other embodiments, the peak-to-peak rectifier 102 can include amplifier-based rectifiers, such as illustrated in FIG. 6.

FIG. 5 is a schematic diagram of a diode-based peak-to-peak rectifier 500 according to at least one embodiment. The diode-based peak-to-peak rectifier 500 can include a rectifier branch 502 and a reference branch 504. The rectifier branch 502 includes a diode and a capacitor to generate the positive rectified signal 122 of the incoming analog signal 116 and another diode and capacitor to generate the negative rectified signal 124 of the incoming analog signal 116. The reference branch 504 includes a diode and capacitor to generate the positive target signal 126 from the positive bias signal 130, and another diode and capacitor to generate the negative target signal 128 from the negative bias signal 132. The diode-based peak-to-peak rectifier 500 can be a single-ended design or a differential design.

FIG. 6 is a schematic diagram of an amplifier-based peak-to-peak rectifier 600 according to at least one embodiment. The amplifier-based peak-to-peak rectifier 600 includes a rectifier branch 602 and a reference branch 604. In this embodiment, the reference branch 604 is separate from the rectifier branch 602. That is, the reference branch 604 can be a standalone block that can be a separate block or integrated into the reference generator 106. In other embodiments, the rectifier branch 602 and reference branch 604 can be integrated into the same circuitry.

The rectifier branch 602 includes an amplifier, a diode, and a capacitor to generate the positive rectified signal 122 of the incoming analog signal 116 and another amplifier, diode, and capacitor to generate the negative rectified signal 124 of the incoming analog signal 116. The reference branch 604 can generate the positive target signal 126 and negative target signal 128 based on bias 606 received from a reference generator 106. The amplifier-based peak-to-peak rectifier 600 can be a single-ended design or a differential design. The amplifier-based peak-to-peak rectifier 600 can be limited by feedback loop bandwidth, but can be used in low frequency rectifying scenarios.

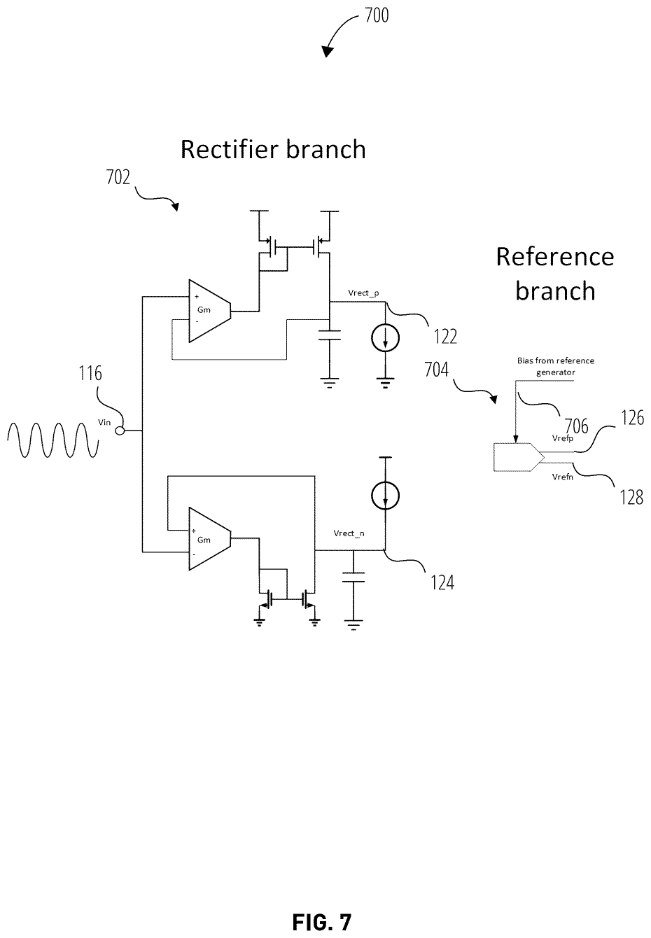

FIG. 7 is a schematic diagram of an amplifier-based peak-to-peak rectifier 700 according to at least one embodiment. The amplifier-based peak-to-peak rectifier 700 includes a rectifier branch 702 and a reference branch 704. In this embodiment, the reference branch 704 is separate from the rectifier branch 702. That is, the reference branch 704 can be a standalone block that can be a separate block or integrated into the reference generator 106. In other embodiments, the rectifier branch 702 and reference branch 704 can be integrated into the same circuitry.

The rectifier branch 702 includes an amplifier, a transistor pair, and a capacitor to generate the positive rectified signal 122 of the incoming analog signal 116 and another amplifier, transistor pair, and capacitor to generate the negative rectified signal 124 of the incoming analog signal 116. The reference branch 704 can generate the positive target signal 126 and negative target signal 128 based on bias 706 received from a reference generator 106. The amplifier-based peak-to-peak rectifier 700 can be a single-ended design or a differential design. The amplifier-based peak-to-peak rectifier 700 can be limited by feedback loop bandwidth, but can be used in low frequency rectifying scenarios.

FIG. 8 is a schematic diagram of a reference generator 800 according to at least one embodiment. The reference generator 800 includes a temperature-compensated current source 802 and a voltage DAC 804 (also referred to as a resistor DAC or resistor ladder). The temperature-compensated current source 802 can generate a mixed current, Imix, by mixing two current DACs which have different temperature slopes. For example, the two current source can be Proportional To Absolute Temperature (PTAT) current source and bandgap current sources. As illustrated in FIG. 8, the two currents, Iref1 and Iref2 have different temperature coefficients. By controlling current generated by the two current DACs, IDAC1 and IDAC2, the mixed current, Imix, can have tunable temperature coefficient. The voltage DAC 804 can include a resistor ladder to convert mixed current, Imix, to voltages with the temperature coefficient. An alternative is to use Transimpedance Amplifier (TIA) Resistor ladder that has control bits to control the voltage value. As described above, the temperature-compensated current source 802 can mix current to generate current according to a temperature slope. The temperature-compensated current source 802 can supply current to the voltage DAC 804, which is used to choose a detection threshold. In particular, the voltage DAC 804 can be used to generate the positive bias signal 130, negative bias signal 132, and common mode signal 134 described above.

FIG. 9 is a schematic diagram of a linear combiner 900 according to at least one embodiment. The linear combiner 900 includes two transconductance (Gm) amplifiers 902 that are used to convert an input voltage to current so that the current can be added in the current domain. The linear combiner 900 also includes resistors (R) and a common-mode feedback (CMFB) circuit 904 to convert the combined current to a voltage with a suitable common mode voltage to send to a comparator 906. The comparator 906 receives the voltages and compares them to obtain the output signal 118. The output signal 118 can be sent to a digital IDF to reduce noise, as described above.

In at least one embodiment, the linear combiner 900 includes a first transistor pair to receive the positive rectified signal 122 and the positive target signal 126, and a second transistor pair to receive the negative rectified signal 124 and the negative target signal 128. The first transistor pair and the second transistor pair convert input voltages to input currents and add the input currents to obtain combined currents. The linear combiner 900 includes a third transistor pair to convert the combined currents into voltages to send to the comparator 906. The comparator 906 can compare the voltages and output the output signal 118 indicative of the peak-to-peak amplitude of the incoming analog signal 116. The output signal 118 can be a digital value that is output to a digital filter to reduce noise in the output signal 118. Alternatively, the output signal 118 can be an analog signal that is output to an analog processing circuit.

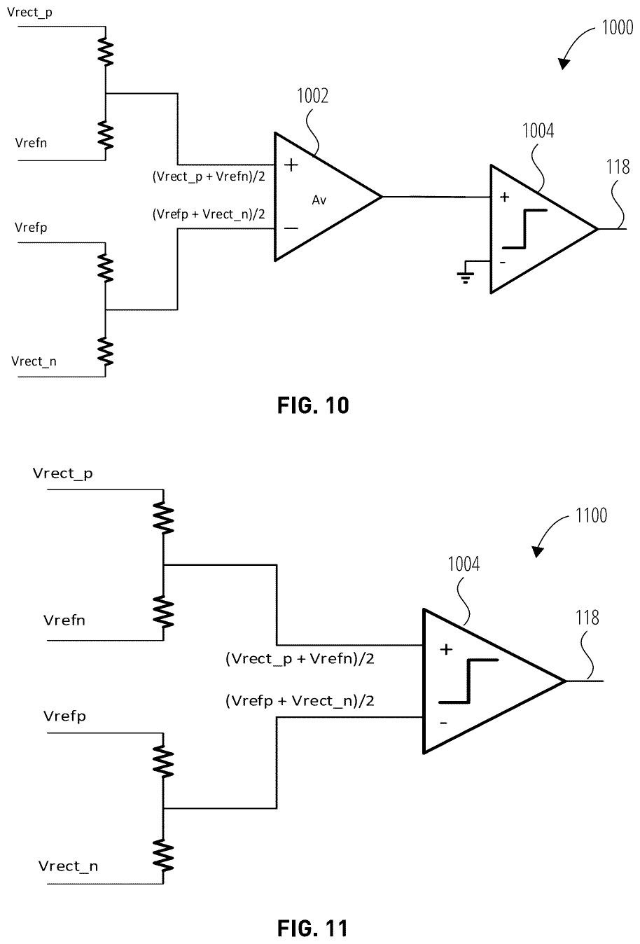

It should be noted that the linear combiner 900 is one implementation of the linear combiner 104. In other embodiments, the linear combiner 104 can include other circuit configurations, such as illustrated and described below with respect to FIG. 10 to FIG. 12.

FIG. 10 is a schematic diagram of a linear combiner 1000 according to at least one embodiment. The linear combiner 1000 includes an amplifier 1002 and a comparator 1004 (or slicer). The linear combiner 1000 can add the voltage signals in the voltage domain by inputting an averaged rectified and target voltage (e.g., (Vrect_p+Vrefn)/2) in a positive terminal of the amplifier 1002 and another averaged rectified and target voltage (e.g., (Vrect_n+Vrefp)/2) in a negative terminal of the amplifier 1002. The amplifier 1002 outputs a voltage signal that can be digitized by the comparator 1004, which outputs the output signal 118. In this embodiment, the second input of the comparator 1004 is coupled to ground (or other specified voltage potential).

FIG. 11 is a schematic diagram of a linear combiner 1100 according to at least one embodiment. The linear combiner 1100 is similar to the linear combiner 1000, except without the amplifier 1002. In this embodiment, one of the averaged signals is input into a positive input of the comparator 1004 and another averaged signal is input into a negative input of the comparator 1004. The comparator 1004 outputs the output signal 118.

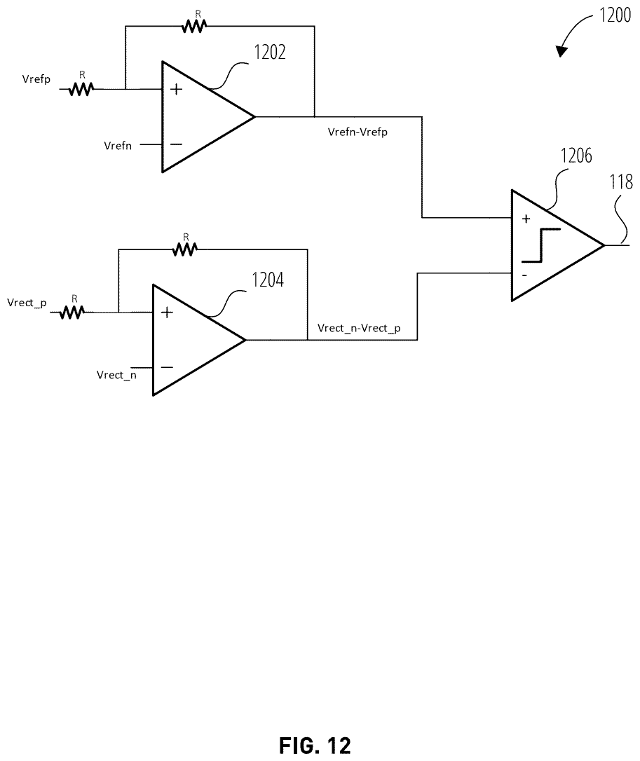

FIG. 12 is a schematic diagram of a linear combiner 1200 according to at least one embodiment. The linear combiner 1200 includes an amplifier 1202, an amplifier 1204, and a comparator 1206 (or slicer). The amplifier 1202 can determine a difference signal (e.g., Vrefn−Vrefp) between the target reference voltages, which is input into a positive input of the comparator 1206. The amplifier 1204 can determine a difference signal (Vrect_n−Vrect_p) between the rectified voltages, which is input into a negative input of the comparator 1206. The difference between these difference signals can be digitized by the comparator 1206, which outputs the output signal 118. Alternate variations of these current-based or voltage-based linear combiners can be used.

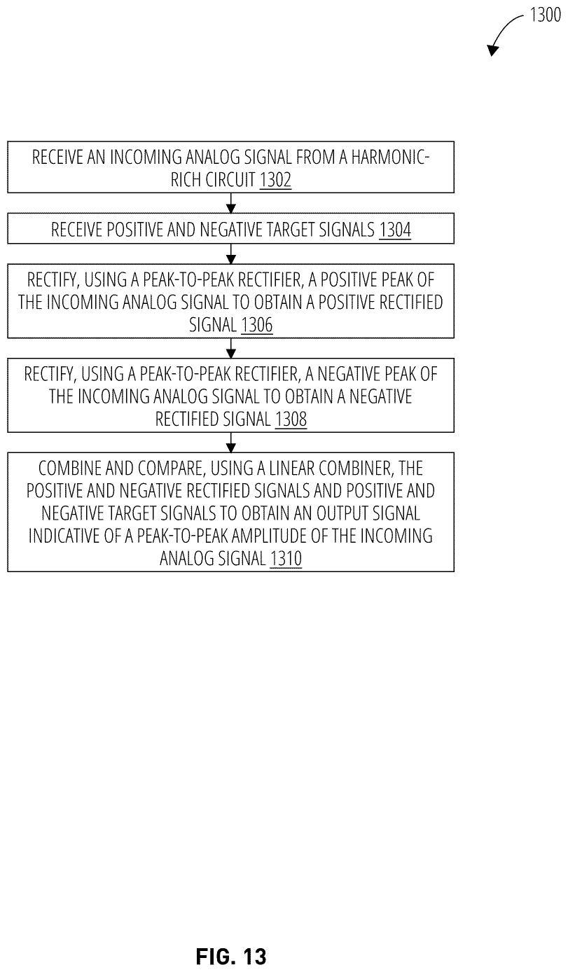

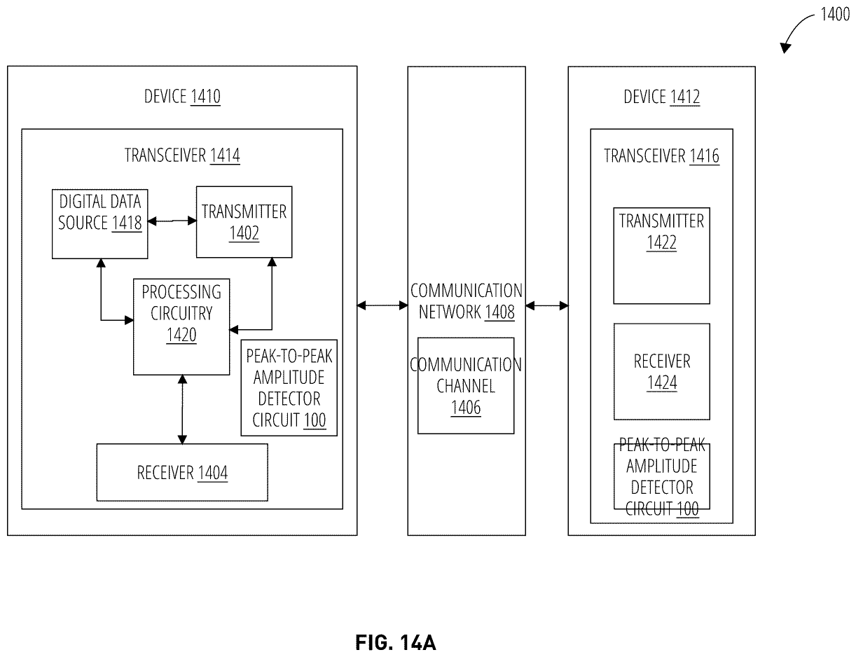

FIG. 13 is a flow diagram of an example method 1300 for determining a peak-to-peak amplitude of an incoming signal according to at least one embodiment. The method 1300 can be performed using the peak-to-peak amplitude detector circuit 100 of FIG. 1. The peak-to-peak amplitude detector circuit 100 can be part of one or more processing units (e.g., CPUs, GPUs, accelerators, physics processing units (PPUs), data processing units (DPUs), etc.), which may include (or communicate with) one or more memory devices. In at least one embodiment, the method 1300 can be performed using a processing device or processing devices. In at least one embodiment, the method 1300 or portions of the method 1300 can be performed by any of the components described above with respect to FIG. 1 to FIG. 12. Some operations of the method 1300 can be performed concurrently with other operations. In at least one embodiment, one or more operations shown in FIG. 13 may not always be performed.

Referring to FIG. 13, the method 1300 begins by the processing logic receiving an incoming analog signal from a harmonic-rich circuit (block 1302). At block 1304, the processing logic receives positive and negative target signals. At block 1306, the processing logic rectifies, using a peak-to-peak rectifier, a positive peak of the incoming analog signal to obtain a positive rectified signal. At block 1308, the processing logic rectifies, using a peak-to-peak rectifier, a negative peak of the incoming analog signal to obtain a negative rectified signal. At block 1310, the processing logic combines and compares, using a linear combiner, the positive and negative rectified signals and positive and negative target signals to obtain an output signal indicative of a peak-to-peak amplitude of the incoming analog signal.

In a further embodiment, the processing logic can generate, using a reference generator, a positive bias signal and a negative bias signal. The processing logic can generate, using a reference branch of the peak-to-peak rectifier and the positive and negative bias signals, the positive and negative target signals. The positive and negative rectified signals can be rectified by a rectifier branch of the peak-to-peak rectifier. The processing logic provides the positive and negative rectified signals and the positive and negative target signals to the linear combiner.

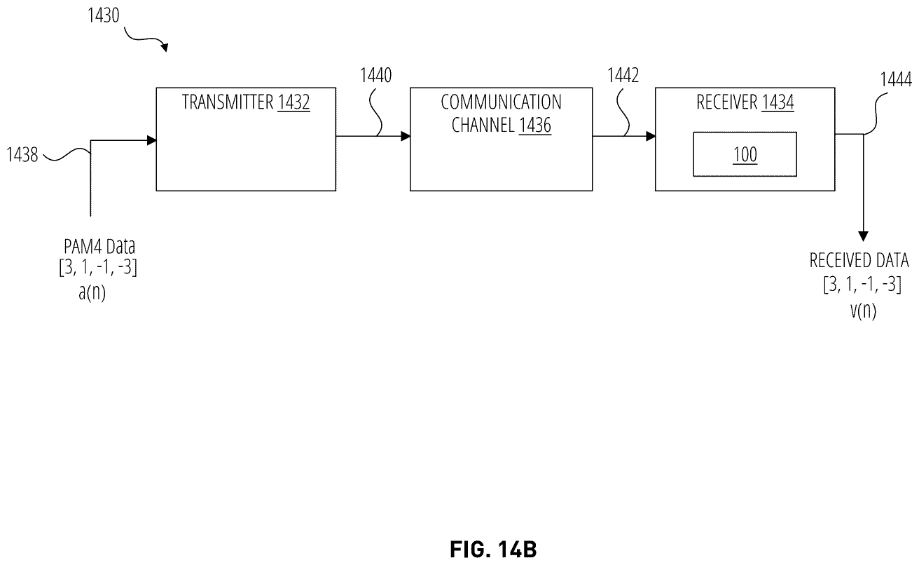

FIG. 14A illustrates an example communication system 1400 with a peak-to-peak amplitude detector circuit 100 according to at least one embodiment. The communication system 1400 includes a device 1410, a communication network 1408 including a communication channel 1406, and a device 1412. In at least one embodiment, the devices 1410 and 1412 are integrated circuits of a Personal Computer (PC), a laptop, a tablet, a smartphone, a server, a collection of servers, or the like. In some embodiments, the devices 1410 and 1412 may correspond to any appropriate type of device that communicates with other devices also connected to a common type of communication network 1408. According to embodiments, the transmitter 1402 and 1422 of devices 1410 or 1412 may correspond to transmitters of a Graphics Processing Unit (GPU), a switch (e.g., a high-speed network switch), a network adapter, a central processing unit (CPU), a data processing unit (DPU), etc.

Examples of the communication network 1408 that may be used to connect the devices 1410 and 1412 include wires, conductive traces, bumps, terminals, optical fibers, or the like. In other embodiments, the communication network 1408 can be a Peripheral Component Interconnect Express (PCIe) interconnect. PCIe is a high-speed interface standard used to connect various hardware components. It can be an interconnect for devices such as graphics cards (GPUs), solid-state drives (SSDs), network cards, and other peripherals. PCIe offers a scalable, high-speed, and point-to-point connection between devices, including CPUs, GPUs, memory, and the like. In other embodiments, the communication network 1408 can be a high-speed interconnect, such as an interconnect that deploys the NVLink technology. The NVLink interconnect can be a GPU-GPU interconnect used between GPUs, a CPU-GPU interconnect between GPUs and CPUs, or an interconnect used between other devices. NVLink offers a higher bandwidth and lower latency than traditional PCIe connections, which are typically used in computing hardware. NVLink is especially useful in scenarios that require massive parallel processing, such as artificial intelligence (AI), machine learning, deep learning, high-performance computing (HPC), and data analytics. For example, in NVIDIA's DGX systems and high-end gaming or AI workstations, NVLink helps GPUs exchange data at speeds that are necessary for demanding tasks like real-time ray tracing or training neural networks. In one specific, but non-limiting example, the communication network 1408 is a network that enables data transmission between the devices 1410 and 1412 using data signals (e.g., digital, optical, wireless signals), clock signals, or both. The embodiments described herein can be utilized in a system with a high-speed, scalable switch, such as a switch using the NVSwitch technology. NVSwitch is a high-speed, scalable switch developed by NVIDIA that facilitates data communication between multiple GPUs in a system, allowing them to work together more efficiently by providing high-bandwidth, low-latency interconnections. The NVSwitch serves as a central hub or high-bandwidth fabric that interconnects all the GPUs in a system, enabling each GPU to communicate with every other GPU quickly and efficiently. The NVSwitch can be coupled between other types of devices, such as CPUs, accelerators, memory, or the like. The NVSwitch can be used for tasks requiring intense computation and collaboration between multiple GPUs, such as AI model training, scientific simulations, and large-scale data processing. The embodiments described herein can be used in a high-performance computing system, such as a computing system modeled after NVIDIA's DGX systems, which are designed specifically for artificial intelligence (AI), deep learning, and high-performance computing (HPC) workloads. DGX systems are optimized for large-scale GPU computation and parallel processing, integrating multiple GPUs, high-bandwidth interconnects, and software frameworks tailored for AI and HPC tasks. In at least one embodiment, a system for high-speed network communication includes a processing unit, a network interface comprising a receiver or transceiver with a peak-to-peak amplitude detector circuit 100. The processing unit can include a CPU, a GPU, a DPU, a network adapter, a network switch, an NVLink switch, or the like. 2436, as described herein.

Other examples for the communication network 1408 can include other chip-to-chip or die-to-die interconnects, such as GRS, LPI (low power interface) or LLI (low latency interface).

The device 1410 includes a transceiver 1414 for sending and receiving signals, for example, data signals. The data signals may be digital or optical signals modulated with data or other suitable signals for carrying data.

The transceiver 1414 may include a digital data source 1418, a transmitter 2402, a receiver 1404, and processing circuitry 1420 that controls the transceiver 1414. The digital data source 1418 may include suitable hardware and/or software for outputting data in a digital format (e.g., in binary code and/or thermometer code). The digital data output by the digital data source 1418 may be retrieved from memory (not illustrated) or generated according to input (e.g., user input). The transceiver 1414 can include the peak-to-peak amplitude detector circuit 100 as described above with respect to FIG. 1 to FIG. 12.

The transceiver 1414 includes suitable software and/or hardware for receiving digital data from the digital data source 1418 and outputting data signals according to the digital data for transmission over the communication network 1408 to a transceiver 1416 of device 1412.

The receiver 1404 of device 1410 may include suitable hardware and/or software for receiving signals, for example, data signals from the communication network 1408. For example, the receiver 1404 may include components for receiving processing signals to extract the data for storing in a memory. In at least one embodiment, the transceiver 1416 includes a transmitter 1422 and receive 1424. The transceiver 1416 receives an incoming signal and samples the incoming signal to generate samples, such as using an analog-to-digital converter (ADC). The ADC can be controlled by a clock-recovery circuit (or clock recovery block) in a closed-loop tracking scheme. The clock-recovery circuit can include a controlled oscillator, such as a voltage-controlled oscillator (VCO) or a digitally-controlled oscillator (DCO) that controls the sampling of the subsequent data by the ADC. The transceiver 1416 can include the peak-to-peak amplitude detector circuit 100 as described above with respect to FIG. 1 to FIG. 12.

The processing circuitry 1420 may comprise software, hardware, or a combination thereof. For example, the processing circuitry 1420 may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory). Additionally or alternatively, the processing circuitry 1420 may comprise hardware, such as an Application-Specific Integrated circuit (ASIC). Other non-limiting examples of the processing circuitry 1420 include an Integrated Circuit (IC) chip, a CPU, A GPU, a DPU, a microprocessor, a Field-Programmable Gate Array (FPGA), a collection of logic gates or transistors, resistors, capacitors, inductors, diodes, or the like. Some or all of the processing circuitry 1420 may be provided on a Printed Circuit Board (PCB) or collection of PCBs. It should be appreciated that any appropriate type of electrical component or collection of electrical components may be suitable for inclusion in the processing circuitry 1420. The processing circuitry 1420 may send and/or receive signals to and/or from other elements of the transceiver 1414 to control the overall operation of the transceiver 1414.

The transceiver 1414 or selected elements of the transceiver 1414 may take the form of a pluggable card or controller for the device 1410. For example, the transceiver 1414 or selected elements of the transceiver 1414 may be implemented on a network interface card (NIC).

The device 1412 may include a transceiver 1416 for sending and receiving signals, for example, data signals over a communication channel 1406 of the communication network 1408. The channel 2406 can be PCIe, NVLink, Ethernet, InfiniBand, Ground Reference Signal (GRS), Chip-to-Chip (C2C), Die-to-Die (D2D), or the like. The same or similar structure of the transceiver 1414 may be applied to transceiver 1416, and thus, the structure of transceiver 1416 is not described separately.

Although not explicitly shown, it should be appreciated that devices 1410 and 1412 and the transceiver 1414 and transceiver 1416 may include other processing devices, storage devices, and/or communication interfaces generally associated with computing tasks, such as sending and receiving data.

FIG. 14B illustrates a block diagram of an example communication system 1430 employing a receiver 1434 with a peak-to-peak amplitude detector circuit 100 according to at least one embodiment. In the example shown in FIG. 14B, a Pulse Amplitude Modulation level-4 (PAM4) modulation scheme is employed with respect to the transmission of a signal (e.g., digitally encoded data) from a transmitter (TX) 1432 to a receiver (RX) 1434 via a communication channel 1436 (e.g., a transmission medium). The communication channel 2406 can be PCIe, NVLink, Ethernet, InfiniBand, GRS, C2C, D2D, or the like. In this example, the transmitter 1432 receives an input data 1438 (i.e., the input data at time n is represented as “a(n)”), which is modulated in accordance with a modulation scheme (e.g., PAM4) and sends the signal 1440 a(n) including a set of data symbols (e.g., symbols −3, −1, 1, 3, where the symbols represent coded binary data). It is noted that while the use of the PAM4 modulation scheme is described herein by way of example, other data modulation schemes can be used in accordance with embodiments of the present disclosure, including for example, a non-return-to-zero (NRZ) modulation scheme, PAM3, PAM7, PAM8, PAM16, etc. For example, for an NRZ-based system, the transmitted data symbols consist of symbols −1 and 1, with each symbol value representing a binary bit. This is also known as a PAM level-2 or PAM2 system as there are 2 unique values of transmitted symbols. Typically, a binary bit 0 is encoded as −1, and a bit 1 is encoded as 1 as the PAM2 values.

In the example shown, the PAM4 modulation scheme uses four (4) unique values of transmitted symbols to achieve higher efficiency and performance. The four levels are denoted by symbol values −3, −1, 1, 3, with each symbol representing a corresponding unique combination of binary bits (e.g., 00, 01, 10, 11).

The communication channel 1436 is a destructive medium in that the channel acts as a low pass filter which attenuates higher frequencies more than it attenuates lower frequencies, introduces inter-symbol interference (ISI) and noise from cross talk, from power supplies, from Electromagnetic Interference (EMI), or from other sources. The communication channel 1436 can be over serial links (e.g., a cable, PCB traces, copper cables, optical fibers, or the like), read channels for data storage (e.g., hard disk, flash solid-state drives (SSDs), high-speed serial links, deep space satellite communication channels, applications, or the like. The receiver (RX) 1434 receives an incoming signal 1442 over the communication channel 1436. The receiver 1434 can output a received signal 1444, “v(n),” including the set of data symbols (e.g., symbols −3, −1, 1, 3, wherein the symbols represent coded binary data).

In at least one embodiment, the transmitter 1432 can be part of a SerDes IC. The SerDes IC can be a transceiver that converts parallel data to serial data and vice versa. The SerDes IC can facilitate transmission between two devices over serial streams, reducing the number of data paths, wires/traces, terminals, etc. The receiver 1434 can be part of a SerDes IC. The SerDes IC can include a clock-recovery circuit. The clock-recovery circuit can be coupled to an ADC and an equalization block. In another embodiment, the SerDes IC can include additional equalization block before a symbol detector.

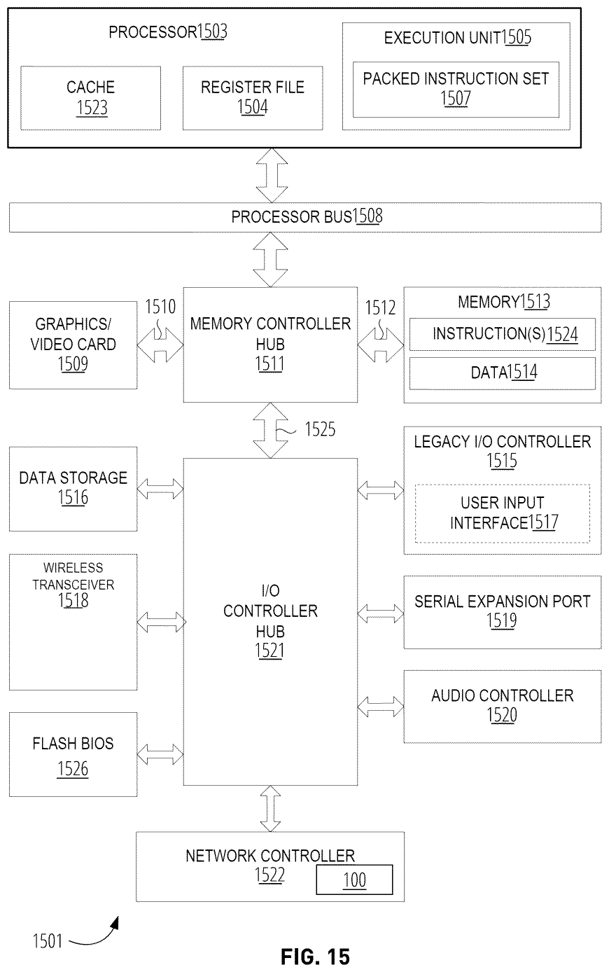

FIG. 15 illustrates an example computer system 1501, including an error correction circuit 1530, in accordance with at least some embodiments. In at least one embodiment, computer system 1501 may be a system with interconnected devices and components, an SOC, or some combination. In at least one embodiment, computer system 1501 is formed with a processor 1503 that may include execution units to execute an instruction. In at least one embodiment, computer system 1501 may include, without limitation, a component, such as a processor 1503, to employ execution units including logic to perform algorithms for processing data. In at least one embodiment, computer system 1501 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 1501 may execute a version of WINDOWS' operating system available from Microsoft Corporation of Redmond, Wash., although other operating systems (UNIX and Linux, for example), embedded software, and/or graphical user interfaces, may also be used.

In at least one embodiment, computer system 1501 may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (DSP), an SoC, network computers (“NetPCs”), set-top boxes, network hubs, wide area network (“WAN”) switches, or any other system that may perform one or more instructions. In an embodiment, computer system 1501 may be used in devices such as graphics processing units (GPUs), network adapters, central processing units, and network devices such as switches (e.g., a high-speed direct GPU-to-GPU interconnect such as the NVIDIA GH100 NVLINK or the NVIDIA Quantum 2 64 Ports InfiniBand NDR Switch).

In at least one embodiment, computer system 1501 may include, without limitation, processor 1503 that may include, without limitation, one or more execution units 1505 that may be configured to execute a Compute Unified Device Architecture (“CUDA”) (CUDA® is developed by NVIDIA Corporation of Santa Clara, CA) program. In at least one embodiment, a CUDA program is at least a portion of a software application written in a CUDA programming language. In at least one embodiment, computer system 1501 is a single processor desktop or server system. In at least one embodiment, computer system 1501 may be a multiprocessor system. In at least one embodiment, processor 1503 may include, without limitation, a CISC microprocessor, a RISC microprocessor, a VLIW microprocessor, and a processor implementing a combination of instruction sets, or any other processor device, such as a digital signal processor, for example. In at least one embodiment, processor 1503 may be coupled to a processor bus 1508 that may transmit data signals between processor 1503 and other components in computer system 1501.

In at least one embodiment, processor 1503 may include, without limitation, a Level 1 (“L1”) internal cache memory (“cache”) 1523. In at least one embodiment, processor 1503 may have a single internal cache or multiple levels of internal cache. In at least one embodiment, cache memory may reside external to processor 1503. In at least one embodiment, processor 1503 may also include a combination of both internal and external caches. In at least one embodiment, a register file 1504 may store different types of data in various registers including, without limitation, integer registers, floating point registers, status registers, and instruction pointer register.

In at least one embodiment, execution unit 1505, including, without limitation, logic to perform integer and floating point operations, also resides in processor 1503. Processor 1503 may also include a microcode (“ucode”) read only memory (“ROM”) that stores microcode for certain macro instructions. In at least one embodiment, execution unit 1505 may include logic to handle a packed instruction set 1507. In at least one embodiment, by including packed instruction set 1507 in an instruction set of a general-purpose processor 1503, along with associated circuitry to execute instructions, operations used by many multimedia applications may be performed using packed data in a general-purpose processor 1503. In at least one embodiment, many multimedia applications may be accelerated and executed more efficiently by using full width of a processor's data bus for performing operations on packed data, which may eliminate a need to transfer smaller units of data across a processor's data bus to perform one or more operations one data element at a time.

In at least one embodiment, execution unit 1506 may also be used in microcontrollers, embedded processors, graphics devices, DSPs, and other types of logic circuits. In at least one embodiment, computer system 1501 may include, without limitation, a memory 1513. In at least one embodiment, memory 1513 may be implemented as a DRAM device, an SRAM device, flash memory device, or other memory devices. Memory 1513 may store instruction(s) 1524 and/or data 1514 represented by data signals that may be executed by processor 1503.

In at least one embodiment, a system logic chip may be coupled to a processor bus 1508 and memory 1513. In at least one embodiment, the system logic chip may include, without limitation, a memory controller hub (“MCH”) 1511, and processor 1503 may communicate with MCH 1511 via processor bus 1508. In at least one embodiment, MCH 1511 may provide a high bandwidth memory path 1512 to memory 1513 for instruction and data storage and for storage of graphics commands, data, and textures. In at least one embodiment, MCH 1511 may direct data signals between processor 1503, memory 1513, and other components in computer system 1501 and may bridge data signals between processor bus 1508, memory 1513, and a system I/O 1525. In at least one embodiment, a system logic chip may provide a graphics port for coupling to a graphics controller. In at least one embodiment, MCH 1511 may be coupled to memory 1513 through high bandwidth memory path 1512, and graphics/video card 1509 may be coupled to MCH 1511 through an Accelerated Graphics Port (“AGP”) interconnect 1510.

In at least one embodiment, computer system 1501 may use system I/O 1525 that is a proprietary hub interface bus to couple MCH 1511 to I/O controller hub (“ICH”) 1521. In at least one embodiment, ICH 1521 may provide direct connections to some I/O devices via a local I/O bus. In at least one embodiment, a local I/O bus may include, without limitation, a high-speed I/O bus for connecting peripherals to memory 1513, a chipset, and processor 1503. Examples may include, without limitation, an audio controller 1520, a firmware hub (“flash BIOS”) 726, a wireless transceiver 1518, a data storage 1516, a legacy I/O controller 1515 containing a user input interface 1517, a keyboard interface, a serial expansion port 1519, such as a USB, and a network controller 1522. In at least one embodiment, the network controller 1522 includes the peak-to-peak amplitude detector circuit 100 as described herein. Data storage 1516 may comprise a hard disk drive, a floppy disk drive, a CD-ROM device, a flash memory device, or other mass storage device.

In at least one embodiment, FIG. 15 illustrates a system, which includes interconnected hardware devices or “chips.” In at least one embodiment, FIG. 15 may illustrate an example SoC. In at least one embodiment, devices illustrated in FIG. 15 may be interconnected with proprietary interconnects, standardized interconnects (e.g., PCIe), or some combination thereof. In at least one embodiment, one or more components of system 1502 are interconnected using compute express link (“CXL”) interconnects.

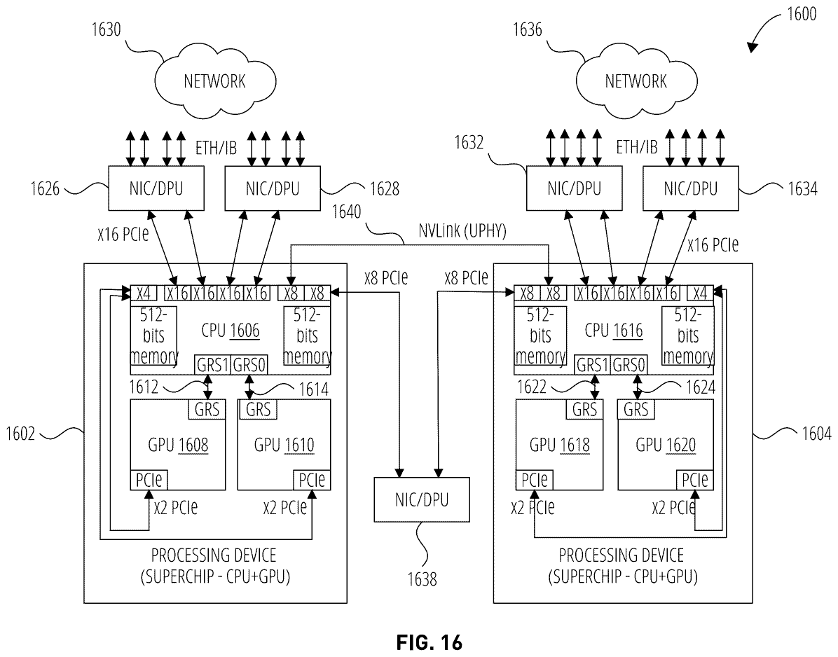

FIG. 16 is a block diagram of a computing system 1600 having two processing devices coupled to each other and multiple networks according to at least one embodiment. The computing system 1600 is designed with multiple integrated circuits (referred to as processing devices), where each integrated circuit includes a CPU and two GPUs, forming a powerful and flexible architecture. These processing devices are interconnected via an NVLink (or other high-speed interconnect), enabling high-speed communication between the processing devices, and are also connected through a Network Interface Card (NIC) or Data Processing Unit (DPU) to ensure efficient data transfer across the computing system 1600. The coupling of processing devices through NVLink allows for seamless data exchange and parallel processing, enhancing overall computational performance. Additionally, these processing devices are connected to multiple networks through one or more network interface cards (NICs) or DPUs, enabling the system to handle complex, multi-network tasks with high bandwidth and low latency. This configuration makes the computing system 1600 highly suitable for demanding applications that require significant processing power, such as artificial intelligence (AI), machine learning (ML), and data-intensive computing, while ensuring robust connectivity and scalability across various networked environments. The integrated circuits of the computing system 1600 can include one or more CPUs and one or more GPUs. An example architecture of a multi-GPU architecture is illustrated in FIG. 16.

As illustrated in FIG. 16, the computing system 1600 includes a processing device 1602 with a multi-GPU architecture. In particular, the processing device 1602 includes a CPU 1606, a GPU 1608, and a GPU 1610. The CPU 1606 can be coupled to the GPU 1608 via an die-to-die (D2D) or chip-to-chip (C2C) interconnect 1612, such as a Ground-Referenced Signaling interconnect (GRS interconnect). The CPU 1606 can be coupled to the GPU 1610 via a D2D or C2C interconnect 1614. The CPU 1606 can also couple to the GPU 1608 and GPU 1610 via PCIe interconnects. The CPU 1606 can be coupled to one or more network interface cards (NICs) or data processing units (DPUs), which are coupled to one or more networks. For example, as illustrated in FIG. 16, the CPU 1606 is coupled to a first NIC/DPU 1626, which is coupled to a network 1630. The CPU 1606 is also coupled to a second NIC/DPU 1628, which is coupled to the network 1630. The NIC/DPU 1626 and NIC/DPU 1628 can be coupled to the network 1630 over Ethernet (ETH) or InfiniBand (IB) connections.

The computing system 1600 also includes a processing device 1604 with a multi-GPU architecture. In particular, the processing device 1604 includes a CPU 1616, a GPU 1618, and a GPU 1620. The CPU 1616 can be coupled to the GPU 1618 via an D2D or C2C interconnect 1622. The CPU 1616 can be coupled to the GPU 1620 via a D2D or C2C interconnect 1624. The CPU 1616 can also couple to the GPU 1618 and GPU 1620 via PCIe interconnects. The CPU 1616 can be coupled to one or more NICs or DPUs, which are coupled to one or more networks. For example, as illustrated in FIG. 16, the CPU 1616 is coupled to a first NIC/DPU 1632, which is coupled to a network 1636. The CPU 1616 is also coupled to a second NIC/DPU 1634, which is coupled to the network 1636. The NIC/DPU 1632 and NIC/DPU 1634 can be coupled to the network 1636 over Ethernet (ETH) or InfiniBand (IB) connections.

In at least one embodiment, the processing device 1602 and the processing device 1604 can communication with each other via a NIC/DPU 1638, such as over PCIe interconnects. The processing device 1602 and processing device 1604 can also communicate with each other over a high-bandwidth communication interconnects 1640, such as an NVLink interconnect or other high-speed interconnects. The NIC/DPUs of FIG. 16 can be the various embodiments of the DPUs described herein. The error correction circuit 140 can be implemented in any receiver device of any of the devices described herein.

In at least one embodiment, the computing system 1600 is used for high-speed network communication and includes a processing unit (e.g., CPU 1606, GPU 1608, GPU 1610, CPU 1616, GPU 1618, GPU 1620, NIC/DPU 1626, NIC/DPU 1628, NIC/DPU 1632, NIC/DPU 1634, or NIC/DPU 1638), and a network interface coupled to the processing unit. The network interface can include the operations and functionality of the DPUs described herein.

In at least one embodiment, the computing system 1600 includes a host device and an auxiliary device. The auxiliary device includes a device memory and a processor, communicably coupled to the device memory. The auxiliary device performs the operations described herein with respect to FIG. 1 to FIG. 9. The auxiliary device can include a GPU. The auxiliary device can include a DPU. The auxiliary device can include a DPU. The auxiliary device can include accelerator hardware.

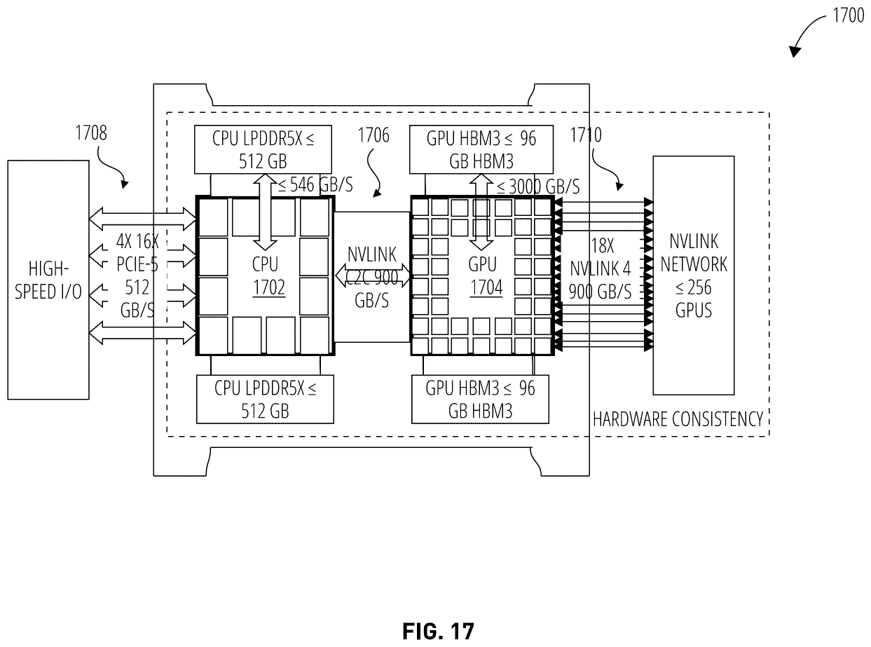

FIG. 17 is a block diagram of a computing system 1700 having a CPU 1702 and a GPU 1704 in a single integrated circuit according to at least one embodiment. The computing system 1700 can be a highly integrated design where a CPU 1702 and GPU 1704 are connected on a single integrated circuit, utilizing an NVLink C2C (Chip-to-Chip) interconnect 1706 to enable fast, low-latency communication between the two processing units. This close integration allows for efficient data transfer and parallel processing between the CPU 1702 and GPU 1704, optimizing performance for complex computational tasks. The GPU elements within the computing system 1700 can be interconnected using an NVLink network, allowing for scalability up to 256 GPU elements, creating a powerful, unified processing environment ideal for large-scale AI, ML, and high-performance computing applications. The NVLink network can be a GPU fabric of high-bandwidth communication interconnects 1710. Additionally, the computing system 1700 can be designed to interface with a high-speed I/O through PCIe interconnects 1708, ensuring rapid data transfer to and from external devices, further enhancing the system's capabilities in handling data-intensive tasks and providing robust connectivity to peripheral components. It should be noted that the C2C interconnects 1706 can be considered D2D interconnects since the CPU 1702 and the GPU 1704 are located on the same integrated circuit. The integrated circuit can include CPU memory (also referred to as main memory) and GPU memory, which are accessible by the CPU 1702 and the GPU 1704, respectively, over high-speed interconnects. The computing system 1700 can bring together performance of the GPU 1704 with the versatility of the CPU 1702. The CPU 1702 can be connected with a high-bandwidth and memory coherent C2C interconnects 1706 in a single integrated circuit. The computing system 1700 can support a link switch system.

The computing system 1700 can include the error correction circuit 140 used for the various embodiments described herein with respect to FIG. 1 to FIG. 9. The error correction circuit 140 can be implemented in any receiver device of any of the devices described herein.

In at least one embodiment, the computing system 1700 is used for high-speed network communication and includes a processing unit, and a network interface coupled to the processing unit. The network interface can include the operations and functionality of the DPUs described herein.

In at least one embodiment, the computing system 1700 includes a host device and an auxiliary device. The auxiliary device includes a device memory and a processor, communicably coupled to the device memory. The auxiliary device performs the operations described herein with respect to FIG. 1 to FIG. 9. The auxiliary device can include a GPU. The auxiliary device can include a DPU. The auxiliary device can include a DPU. The auxiliary device can include accelerator hardware.

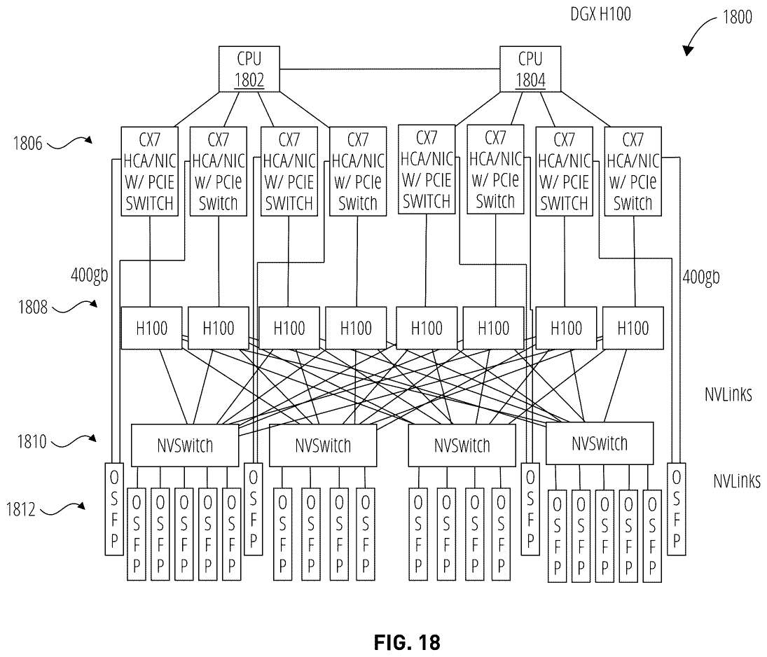

FIG. 18 is a block diagram of a computing system 1800 having tensor core GPUs 1808 according to at least one embodiment. The computing system 1800 can be a DGX H100 system, which is a high-performance computing platform designed to meet the demands of AI, ML, and deep learning (DL) workloads. The computing system 1800 can include multiple tensor core GPUs 1808 (e.g., NVIDIA H100 Tensor Core GPUs). The tensor core GPUs 1808 can each be one of the integrated circuits described above with respect to FIG. 15. The tensor core GPUs 1808 can be optimized for AI/ML/DL applications, offering exceptional performance for deep learning training, inference, and high-performance computing tasks. The tensor core GPUs 1808 within the computing system 1800 are interconnected using high-speed communication interfaces like NVLinks, enabling rapid data transfer between them, which is crucial for handling large-scale AI models and datasets with low latency. This computing system 1800 is designed for scalability, allowing for the integration of additional GPUs as required, making it versatile enough for research, development, and deployment in data centers for production AI workloads. Each GPU is equipped with Tensor Cores, specialized processing units that accelerate matrix operations, a fundamental component of AI and deep learning algorithms. These Tensor Cores enable the system to perform mixed-precision calculations efficiently, balancing speed and accuracy. Given the power consumption and heat generation of multiple tensor core GPUs 1808, the computing system 1800 can include advanced cooling solutions and power management features to ensure safe operation while maintaining peak performance. It is supported by a comprehensive software ecosystem, including NVIDIA's CUDA programming model, AI frameworks like TensorFlow and PyTorch, and other HPC and AI software tools, which enable developers and researchers to harness the full power of the tensor core GPUs 1808 for their specific applications. The computing system 1800 is ideally suited for large-scale AI model training, real-time inference, scientific simulations, data analytics, and other compute-intensive tasks that require massive parallel processing power.

The tensor core GPUs 1808 can be coupled to multiple CPUs, such as CPU 1802 and CPU 1804, using switches 1806 (e.g., CX7 HCA/NIC with PCIe switch). The tensor core GPUs 1808 can be coupled to each other via switches 1810 (e.g., NVSwitches). The switches 1806 and switches 1810 can be coupled to high-speed transceiver modules 1812. The high-speed transceiver modules 1812 can be Octal Small Form-factor Pluggable (OSFP) modules. OSFP modules refer to high-speed transceiver modules designed for rapid data communication, particularly in environments requiring significant bandwidth, such as data centers and high-performance computing systems. These modules support extremely high data rates, typically up to 400 Gbps per module, with future capabilities extending to 800 Gbps or more. OSFP modules interface with the system via the PCIe interface, enabling fast and efficient data transfer between the integrated CPU-GPU components and external networks or other connected systems. Their hot-pluggable nature allows for easy insertion or removal without the need to power down the system, offering flexibility and ease of maintenance, which is crucial in critical-uptime environments. Additionally, OSFP modules are designed for high density, maximizing the number of high-speed connections within limited space, such as in densely packed server racks. By adhering to the latest networking standards, OSFP modules ensure the computing system 1800 remains capable of meeting increasing data demands and can be upgraded to support future advancements in network speeds, thus contributing to the system's overall performance and scalability.

In at least one embodiment, the computing system 1800 can be considered a data-network configuration with full-bandwidth intra-server NVLinks. In this example, all eight tensor core GPUs 1808 can simultaneously saturate eighteen NVLinks to other GPUs within the server. The bandwidth is limited by over-subscription from multiple other GPUs. In another embodiments, data-network configuration can be a half-bandwidth intra-server NVLinks. In this example, all eight tensor core GPUs 1808 can half-subscribe eighteen NVLinks to GPUs in other servers. Four tensor core GPUs 1808 can saturate eighteen NVLinks to GPUs in other servers. This is equivalent of full-bandwidth on AllReduce with Scalable Hierarchical Aggregation and Reduction Protocol (SHARP). The reduction in all-2-all (All2All) bandwidth is a balance with server complexity and costs. In at least one embodiment, all eight tensor core GPUs 1808 can independently transfer data, using Remote Direct Memory Access (RDMA) protocol, over its own dedicated switch (e.g., 400 Gb/s HCA/NIC) in an multi-rail InfiniBand/Ethernet configuration. In this example, 800 GBps of aggregate full-duplex to non-NVLink network devices.

The NICs/switches of computing system 1800 can include the various embodiments described herein with respect to FIG. 1 to FIG. 9.

In at least one embodiment, the computing system 1800 is used for high-speed network communication and includes a processing unit (e.g., CPU 1802, CPU 1804, switches 1806, tensor core GPUs 1808, switches 1810, high-speed transceiver modules 1812), and a network interface coupled to the processing unit. The network interface can include a receiver or a transceiver and perform the corresponding operations and functionalities described herein. The processing unit can include a CPU, a GPU, a DPU, a network adapter, a network switch, an NVLink switch, or the like.

In at least one embodiment, the computing system 1800 includes a host device and an auxiliary device. The auxiliary device includes a device memory and a processor, communicably coupled to the device memory. The auxiliary device performs the operations described herein with respect to FIG. 1 to FIG. 9. The auxiliary device can include a GPU. The auxiliary device can include a DPU. The auxiliary device can include a DPU. The auxiliary device can include accelerator hardware.

Other variations are within the spirit of the present disclosure. Thus, while disclosed techniques are susceptible to various modifications and alternative constructions, certain illustrated embodiments thereof are shown in drawings and have been described above in detail. It should be understood, however, that there is no intention to limit the disclosure to a specific form or forms disclosed, but on the contrary, the intention is to cover all modifications, alternative constructions, and equivalents falling within the spirit and scope of the disclosure, as defined in appended claims.

Use of terms “a” and “an” and “the” and similar referents in the context of describing disclosed embodiments (especially in the context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. The term “connected,” when unmodified and referring to physical connections, is to be construed as partly or wholly contained within, attached to, or joined together, even if there is something intervening. Recitations of ranges of values herein are merely intended to serve as a shorthand method of referring individually to each separate value falling within range unless otherwise indicated herein, and each separate value is incorporated into the specification as if it were individually recited herein. Use of the term “set” (e.g., “a set of items”) or “subset,” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but subset and corresponding set may be equal.

Conjunctive language, such as phrases of the form “at least one of A, B, and C,” or “at least one of A, B, and C,” unless specifically stated otherwise or otherwise clearly contradicted by context, is otherwise understood with the context as used in general to present that an item, term, etc., may be either A or B or C, or any nonempty subset of a set of A and B and C. For instance, in the illustrative example of a set having three members, conjunctive phrases “at least one of A, B, and C” and “at least one of A, B, and C” refers to any of the following sets: {A}, {B}, {C}, {A, B}, {A, C}, {B, C}, {A, B, C}. Thus, such conjunctive language is not generally intended to imply that certain embodiments require at least one of A, at least one of B, and at least one of C each to be present. In addition, unless otherwise noted or contradicted by context, the term “plurality” indicates a state of being plural (e.g., “a plurality of items” indicates multiple items). A plurality is at least two items but can be more when so indicated either explicitly or by context. Further, unless stated otherwise or otherwise clear from context, the phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under the control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause a computer system to perform operations described herein. A set of non-transitory computer-readable storage media, in at least one embodiment, comprises multiple non-transitory computer-readable storage media, and one or more individual non-transitory storage media of multiple non-transitory computer-readable storage media lack all of the code while multiple non-transitory computer-readable storage media collectively store all of the code. In at least one embodiment, executable instructions are executed such that different instructions are executed by different processors—for example, a non-transitory computer-readable storage medium stores instructions, and a main CPU executes some of the instructions while a GPU executes other instructions. In at least one embodiment, different components of a computer system have separate processors, and different processors execute different subsets of instructions.

Accordingly, in at least one embodiment, computer systems are configured to implement one or more services that singly or collectively perform operations of processes described herein, and such computer systems are configured with applicable hardware and/or software that enable the performance of operations. Further, a computer system that implements at least one embodiment of present disclosure is a single device and, in another embodiment, is a distributed computer system comprising multiple devices that operate differently such that the distributed computer system performs operations described herein and such that a single device does not perform all operations.

Use of any and all examples, or exemplary language (e.g., “such as”) provided herein, is intended merely to better illuminate embodiments of the disclosure, and does not pose a limitation on the scope of the disclosure unless otherwise claimed. No language in the specification should be construed as indicating any non-claimed element as essential to the practice of the disclosure.

All references, including publications, patent applications, and patents, cited herein are hereby incorporated by reference to the same extent as if each reference were individually and specifically indicated to be incorporated by reference and were set forth in its entirety herein.

The terms “coupled” and “connected,” along with their derivatives, may be used in the description and claims. It should be understood that these terms may not be intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other but yet still CO-operate or interact with each other.

Unless specifically stated otherwise, it may be appreciated that throughout specification terms such as “processing,” “computing,” “calculating,” “determining,” or like, refer to action and/or processes of a computer or computing system or similar electronic computing devices, that manipulate and/or transform data represented as physical, such as electronic, quantities within computing system's registers and/or memories into other data similarly represented as physical quantities within computing system's memories, registers or other such information storage, transmission or display devices.

In a similar manner, the term “processor” may refer to any device or portion of a device that processes electronic data from registers and/or memory and transforms that electronic data into other electronic data that may be stored in registers and/or memory. As non-limiting examples, a “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes for carrying out instructions in sequence or parallel, continuously, or intermittently. The terms “system” and “method” are used herein interchangeably as far as a system may embody one or more methods, and methods may be considered a system.

In the present document, references may be made to obtaining, acquiring, receiving, or inputting analog or digital data into a subsystem, computer system, or computer-implemented machine. Obtaining, acquiring, receiving, or inputting analog and digital data can be accomplished in a variety of ways, such as by receiving data as a parameter of a function call or a call to an application programming interface. In some implementations, the process of obtaining, acquiring, receiving, or inputting analog or digital data can be accomplished by transferring data via a serial or parallel interface. In another implementation, the process of obtaining, acquiring, receiving, or inputting analog or digital data can be accomplished by transferring data via a computer network from providing entity to acquiring entity. References may also be made to providing, outputting, transmitting, sending, or presenting analog or digital data. In various examples, the process of providing, outputting, transmitting, sending, or presenting analog or digital data can be accomplished by transferring data as an input or output parameter of a function call, a parameter of an application programming interface, or inter-process communication mechanism.

Although the discussion above sets forth example implementations of described techniques, other architectures may be used to implement the described functionality and are intended to be within the scope of this disclosure. Furthermore, although specific distributions of responsibilities are defined above for purposes of discussion, various functions and responsibilities might be distributed and divided in different ways, depending on circumstances.

Furthermore, although the subject matter has been described in language specific to structural features and/or methodological acts, it is to be understood that the subject matter claimed in appended claims is not necessarily limited to specific features or acts described. Rather, specific features and acts are disclosed as exemplary forms of implementing the claims.

What is claimed is:

1. A peak-to-peak amplitude detector circuit comprising:
a peak-to-peak rectifier to rectify a positive peak of an incoming analog signal to obtain a positive rectified signal, and rectify a negative peak of the incoming analog signal to obtain a negative rectified signal; and
a linear combiner to combine and compare the positive and negative rectified signals and positive and negative target signals to obtain an output signal indicative of a peak-to-peak amplitude of the incoming analog signal.

2. The peak-to-peak amplitude detector circuit of claim 1, further comprising a reference generator to generate a positive bias signal, a negative bias signal, and a common mode signal, wherein the peak-to-peak rectifier comprises:
a rectifier branch to receive the incoming analog signal and the common mode signal, rectify the incoming analog signal to obtain the positive rectified signal and the negative rectified signal, and provide the positive rectified signal and the negative rectified signal to the linear combiner; and
a reference branch to receive the positive bias signal and the negative bias signal, generate the positive target signal and the negative target signal using the positive bias signal and the negative bias signal, and provide the positive target signal and the negative target signal to the linear combiner.

3. The peak-to-peak amplitude detector circuit of claim 2, wherein:
the rectifier branch comprises:
a first transistor pair and a first capacitor to generate the positive rectified signal, wherein gates of the first transistor pair are coupled to differential inputs that receive the incoming analog signal, wherein a common voltage node is coupled between the differential inputs and receives the common mode signal from the reference generator; and
a second transistor pair and a second capacitor to generate the negative rectified signal, wherein gates of the second transistor pair are coupled to the differential inputs; and
the reference branch comprises:
a third transistor pair to generate the positive target signal, wherein gates of the third transistor pair are coupled to receive the positive bias signal from the reference generator; and
a fourth transistor pair to generate the negative target signal, wherein gates of the fourth transistor pair are coupled to receive the negative bias signal from the reference generator.

4. The peak-to-peak amplitude detector circuit of claim 2, wherein the linear combiner is to:
combine the following four signals: the positive rectified signal, the negative rectified signal, the positive target signal, and the negative target signal; and
compare differences between the positive and negative rectified signals, and the positive and negative target signals to obtain the output signal indicative of the peak-to-peak amplitude of the incoming analog signal.

5. The peak-to-peak amplitude detector circuit of claim 2, wherein the linear combiner comprises:
a first comparator to compare the positive rectified signal and the positive target signal to obtain a first intermediate signal;
a second comparator to compare the negative rectified signal and the negative target signal to obtain a second intermediate signal; and
an adder to combine the first intermediate signal and the second intermediate signal to obtain the output signal indicative of the peak-to-peak amplitude of the incoming analog signal.

6. The peak-to-peak amplitude detector circuit of claim 1, further comprising a reference generator to generate the positive target signal and the negative target signal, wherein the linear combiner comprises:
a first comparator to compare the positive rectified signal and the positive target signal to obtain a first intermediate signal;
a second comparator to compare the negative rectified signal and the negative target signal to obtain a second intermediate signal; and
an adder to combine the first intermediate signal and the second intermediate signal to obtain the output signal indicative of the peak-to-peak amplitude of the incoming analog signal.

7. The peak-to-peak amplitude detector circuit of claim 1, further comprising a reference generator to generate a positive bias signal, a negative bias signal, and a common mode signal.

8. The peak-to-peak amplitude detector circuit of claim 7, wherein the reference generator comprises a voltage digital-to-analog converter (DAC) to generate the common mode signal, the positive bias signal, and the negative bias signal.

9. The peak-to-peak amplitude detector circuit of claim 8, wherein the reference generator further comprises a temperature-compensated current source coupled to the voltage DAC, the temperature-compensated current source to generate a mixed current having a tunable temperature coefficient.

10. The peak-to-peak amplitude detector circuit of claim 1, wherein the linear combiner comprises:
a first transistor pair to receive the positive rectified signal and the positive target signal;
a second transistor pair to receive the negative rectified signal and the negative target signal, wherein the first transistor pair and the second transistor pair convert input voltages to input currents and add the input currents to obtain combined currents;
a third transistor pair to convert the combined currents into voltages to send to a comparator; and
the comparator to compare the voltages and output the output signal indicative of the peak-to-peak amplitude of the incoming analog signal.

11. The peak-to-peak amplitude detector circuit of claim 10, wherein the output signal is a digital value output to a digital filter to reduce noise in the output signal.

12. A receiver device comprising:
a peak-to-peak rectifier to receive an incoming analog signal and rectify a positive peak and a negative peak of the incoming analog signal;
a reference generator to generate a first reference voltage and a second reference voltage;
a linear combiner coupled to the peak-to-peak rectifier and the reference generator, the linear combiner to:
compare the positive peak and the first reference voltage to obtain a first result;
compare the negative peak and the second reference voltage to obtain a second result;
combine the first result and the second result as an amplitude detection level variation of the incoming analog signal; and
output the amplitude detection level variation to a processing circuit.

13. The receiver device of claim 12, wherein the peak-to-peak rectifier comprises:
a rectifier branch to receive the incoming analog signal and a common mode signal from the reference generator, rectify the incoming analog signal to obtain the positive peak and the negative peak, and provide the positive peak and the negative peak to the linear combiner; and
a reference branch to receive a positive bias signal and a negative bias signal from the reference generator, generate the first reference voltage and the second reference voltage using the positive bias signal and the negative bias signal, and provide the first reference voltage and the second reference voltage to the linear combiner.

14. The receiver device of claim 12, wherein the linear combiner comprises:
a first comparator to compare the positive peak and the first reference voltage to obtain the first result;
a second comparator to compare the negative peak and the second reference voltage to obtain the second result; and
an adder to combine the first result and the second result to obtain the amplitude detection level variation of the incoming analog signal, and output the amplitude detection level variation to the processing circuit.

15. The receiver device of claim 12, wherein the peak-to-peak rectifier comprises:
a first transistor pair and a first capacitor to generate the positive peak, wherein gates of the first transistor pair are coupled to differential inputs that receive the incoming analog signal, wherein a common voltage node is coupled between the differential inputs and receives a common mode signal from the reference generator;
a second transistor pair and a second capacitor to generate the negative peak, wherein gates of the second transistor pair are coupled to the differential inputs;
a third transistor pair to generate the first reference voltage, wherein gates of the third transistor pair are coupled to receive a positive bias signal from the reference generator; and
a fourth transistor pair to generate the second reference voltage, wherein gates of the fourth transistor pair are coupled to receive a negative bias signal from the reference generator.

16. The receiver device of claim 12, wherein the reference generator comprises a voltage digital-to-analog converter (DAC) to generate a common mode signal, a positive bias signal for the peak-to-peak rectifier to generate the first reference voltage, and a negative bias signal for the peak-to-peak rectifier to generate the second reference voltage.

17. The receiver device of claim 16, wherein the reference generator further comprises a temperature-compensated current source coupled to the voltage DAC, the temperature-compensated current source to generate a mixed current having a tunable temperature coefficient.

18. The receiver device of claim 12, wherein the linear combiner comprises:
a first transistor pair to receive the positive peak and the first reference voltage;
a second transistor pair to receive the negative peak and the second reference voltage, wherein the first transistor pair and the second transistor pair convert input voltages to input currents and add the input currents to obtain combined currents;
a third transistor pair to convert the combined currents into voltages to send to a comparator; and
the comparator to compare the voltages and output the amplitude detection level variation to the processing circuit.

19. A communication system for high-speed network communication, the communication system comprising:
a processing unit; and
a network interface coupled to the processing unit, wherein the network interface comprises a receiver device comprising a peak-to-peak amplitude detector circuit comprising:
a peak-to-peak rectifier to rectify a positive peak of an incoming analog signal to obtain a positive rectified signal, and rectify a negative peak of the incoming analog signal to obtain a negative rectified signal; and
a linear combiner to combine and compare the positive and negative rectified signals and positive and negative target signals to obtain an output signal indicative of a peak-to-peak amplitude of the incoming analog signal.

20. The communication system of claim 19, wherein the peak-to-peak amplitude detector circuit further comprises a reference generator to generate a positive bias signal, a negative bias signal, and a common mode signal, wherein the peak-to-peak rectifier comprises:
a rectifier branch to receive the incoming analog signal and the common mode signal, rectify the incoming analog signal to obtain the positive rectified signal and the negative rectified signal, and provide the positive rectified signal and the negative rectified signal to the linear combiner; and
a reference branch to receive the positive bias signal and the negative bias signal, generate the positive target signal and the negative target signal using the positive bias signal and the negative bias signal, and provide the positive target signal and the negative target signal to the linear combiner.

21. The communication system of claim 19, wherein the processing unit comprises at least one of a central processing unit (CPU), a graphics processing unit (GPU), a data processing unit (DPU), a network adapter, a network switch, or an NVLink switch.

22. A method comprising:
receiving an incoming analog signal from a harmonic-rich circuit;
receiving positive and negative target signals;
rectifying, using a peak-to-peak rectifier, a positive peak of the incoming analog signal to obtain a positive rectified signal;
rectifying, using the peak-to-peak rectifier, a negative peak of the incoming analog signal to obtain a negative rectified signal; and
combining and comparing, using a linear combiner, the positive and negative rectified signals and positive and negative target signals to obtain an output signal indicative of a peak-to-peak amplitude of the incoming analog signal.

23. The method of claim 22, further comprising:
generating, using a reference generator, a positive bias signal and a negative bias signal;
generating, using a reference branch of the peak-to-peak rectifier and the positive and negative bias signals, the positive and negative target signals, wherein the positive and negative rectified signals are rectified by a rectifier branch of the peak-to-peak rectifier; and
providing the positive and negative rectified signals and the positive and negative target signals to the linear combiner.
